(19) United States
(12) Patent Application Publication
(10) Pub. No.: US 2026/0188200 A1
(43) Pub. Date: Jul. 2, 2026

(54) Scan Driver and Display Device Including the Same

(71) Applicant: LG Display Co., Ltd., Seoul (KR)

(72) Inventors: Chungsik Kong, Paju-si (KR); Hyungi Shin, Paju-si (KR); Jihui Ku, Paju-si (KR); Minha Kang, Paju-si (KR); Meenwoo Kim, Paju-si (KR); Hyunbin Jeon, Paju-si (KR); Yoosung Jin, Paju-si (KR); Seokjoon Choi, Paju-si (KR); Hyejin Chae, Paju-si (KR); Hyunkyu Lee, Paju-si (KR); Jaechang Kang, Paju-si (KR); Yunseon Hwang, Paju-si (KR); Taehwa Shin, Paju-si (KR); Seounguk Heo, Paju-si (KR)

(21) Appl. No.: 19/431,408

(22) Filed: Dec. 23, 2025

(30) Foreign Application Priority Data
Dec. 31, 2024 (KR) 10-2024-0201775

(51) Int. Cl. G09G 3/32; H10D 86/40

(52) U.S. Cl. CPC G09G 3/32; H10D 86/421; H10D 86/441; G09G 2300/0426; G09G 2310/0267; G09G 2310/0286; G09G 2330/021

(57) ABSTRACT

A scan driver and a display device including the same are presented herein. The scan driver includes a stage configured to receive a clock signal, an output clock signal, and a carry-in signal and output a gate output signal and a carry-out signal. The stage includes a first transistor configured to receive the output clock signal based on a voltage of a first node and output the gate output signal, a second transistor configured to discharge the gate output signal to a gate low voltage based on a voltage of a second node outputting the carry-out signal, a third transistor configured to supply the voltage of the second node to the first node based on the gate low voltage, and a fourth transistor configured to supply the voltage of the first node to the second node based on the voltage of the first node.

### CROSS-REFERENCE TO RELATED APPLICATION

The present application claims priority to Republic of Korea Patent Application No. 10-2024-0201775, filed Dec. 31, 2024, which is incorporated herein by reference in its entirety.

### FIELD

The present disclosure relates to an apparatus and particularly to, for example, without limitation, a scan driver and a display device including the same.

### BACKGROUND

With the development of an information society, demand on various types of display devices has been increasing and various types of display devices such as liquid crystal display (LCD), and organic light emitting display (OLED) devices have been utilized.

A display device may include a plurality of pixels, data lines and scan lines connected to the plurality of pixels, a display driver configured to supply a data voltage to the data lines, and a scan driver configured to supply a scan signal to the scan lines. The display driver and the scan driver may drive the plurality of pixels according to a predetermined frequency.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### SUMMARY

A problem to be solved by the present disclosure is to provide a scan driver capable of securing reliability of a gate output signal by reducing a rise time, a fall time, and a propagation delay, and a display device including the same.

A problem to be solved by the present disclosure is to provide a scan driver capable of reducing a size of a scan driver and reducing power consumption by reducing a buffer size, and a display device including the same.

The technical problem to be achieved by the present disclosure is not limited to the above-mentioned technical problem, and other technical problems that are not mentioned may be inferred from the following embodiments.

In one or more embodiments, a scan driver includes: a stage configured to receive a clock signal, an output clock signal, and a carry-in signal and output a gate output signal and a carry-out signal, and the stage may include: a first transistor configured to receive the output clock signal based on a voltage of a first node and output the gate output signal; a second transistor configured to discharge the gate output signal to a gate low voltage based on a voltage of a second node outputting the carry-out signal; a third transistor configured to supply the voltage of the second node to the first node based on the gate low voltage; and a fourth transistor configured to supply the voltage of the first node to the second node based on the voltage of the first node.

In one or more other embodiments, a display device includes: a display panel comprising data lines configured to supply a data voltage, scan lines intersecting the data lines and configured to supply a scan signal, and pixels connected to the data lines and the scan lines; a display driver configured to supply the data voltage to the data lines; and a scan driver configured to sequentially supply the scan signals to the scan lines, and the scan driver may include: a stage configured to receive a clock signal, an output clock signal, and a carry-in signal and output a gate output signal and a carry-out signal corresponding to the scan signal, and the stage may include: a first transistor configured to receive the output clock signal based on a voltage of a first node and output the gate output signal; a second transistor configured to discharge the gate output signal to a gate low voltage based on a voltage of a second node outputting the carry-out signal; a third transistor configured to supply the voltage of the second node to the first node based on the gate low voltage; and a fourth transistor configured to supply the voltage of the first node to the second node based on the voltage of the first node.

In one or more other embodiments, a scan driver includes: a stage configured to receive a clock signal, an output clock signal, and a carry-in signal and output a gate output signal and a carry-out signal, and the stage may include: a first transistor configured to receive the output clock signal based on a voltage of a first node and output the gate output signal; a second transistor configured to discharge the gate output signal to a gate low voltage based on a voltage of a second node outputting the carry-out signal; a third transistor configured to supply the voltage of the second node to the first node based on a voltage of a third node; a fourth transistor configured to discharge the voltage of the third node to the gate low voltage based on the gate low voltage; and a first capacitor connected between the carry-in signal and the third node.

In one or more other embodiments, a display device includes: a display panel comprising data lines configured to supply a data voltage, scan lines intersecting the data lines and configured to supply a scan signal, and pixels connected to the data lines and the scan lines; a display driver configured to supply the data voltage to the data lines; and a scan driver configured to sequentially supply the scan signals to the scan lines, and the scan driver may include: a stage configured to receive a clock signal, an output clock signal, and a carry-in signal and output a gate output signal and a carry-out signal corresponding to the scan signal, and the stage may include: a first transistor configured to receive the output clock signal based on a voltage of a first node and output the gate output signal; a second transistor configured to discharge the gate output signal to a gate low voltage based on a voltage of a second node outputting the carry-out signal; a third transistor configured to supply the voltage of the second node to the first node based on a voltage of a third node; a fourth transistor configured to discharge the voltage of the third node to the gate low voltage based on the gate low voltage; and a first capacitor connected between the carry-in signal and the third node.

Other details of the embodiments are included in the detailed description and the accompanying drawings.

The scan driver and the display device including the same according to the embodiments of the present disclosure may secure reliability of a gate output signal by reducing a rise time, a fall time, and a propagation delay.

The scan driver and the display device including the same according to the embodiments of the present disclosure may reduce a size of a scan driver and power consumption by reducing a buffer size.

Effects which may be obtained by the present disclosure are not limited to the aforementioned effects, and other technical effects not described above may be evidently understood by a person having ordinary skill in the art to which the present disclosure pertains from the following description.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plan view illustrating a display device according to one or more embodiments of the present disclosure.

FIG. 2 is a block diagram illustrating a display device according to one or more embodiments of the present disclosure.

FIG. 3 is a block diagram illustrating a scan driver of a display device according to one or more embodiments of the present disclosure.

FIG. 4 is a circuit diagram illustrating a stage of a scan driver in a display device according to one or more embodiments of the present disclosure.

FIG. 5 is a waveform diagram illustrating an input/output signal of a stage in a display device according to one or more embodiments of the present disclosure.

FIG. 6 is a waveform diagram illustrating an example of an off-margin of an eighth transistor in a display device according to one or more embodiments of the present disclosure.

FIG. 7 is a graph illustrating an off-margin of an eighth transistor according to a capacitance of a first capacitor in a display device according to one or more embodiments of the present disclosure.

FIG. 8 is a graph illustrating an example of an off-margin of an eighth transistor according to a capacitance of a first capacitor in a display device according to one or more embodiments of the present disclosure.

FIG. 9 is a graph illustrating another example of an off-margin of an eighth transistor according to a capacitance of a first capacitor in a display device according to one or more embodiments of the present disclosure.

FIG. 10 is a graph illustrating still another example of an off-margin of an eighth transistor according to a capacitance of a first capacitor in a display device according to one or more embodiments of the present disclosure.

FIG. 11 is a layout diagram illustrating a stage of a display device according to one or more embodiments of the present disclosure.

FIG. 12 is a cross-sectional view taken along I-I′ line in FIG. 11.

FIG. 13 is a cross-sectional view taken along II-II′ line in FIG. 11.

FIG. 14 is a circuit diagram illustrating a stage of a scan driver in a display device according to one or more other embodiments of the present disclosure.

FIG. 15 is a waveform diagram comparing a voltage of a third node of a stage in FIG. 4 and a stage in FIG. 14.

FIG. 16 is a graph illustrating a rise time of a gate output signal according to a buffer size of a first transistor in a stage of FIG. 4 and a stage of FIG. 14.

FIG. 17 is a graph illustrating a fall time of a gate output signal according to a buffer size of a first transistor in a stage of FIG. 4 and a stage of FIG. 14.

FIG. 18 is a graph illustrating a propagation delay of a gate output signal according to a buffer size of a first transistor in a stage of FIG. 4 and a stage of FIG. 14.

FIG. 19 is a circuit diagram illustrating a stage of a scan driver in a display device according to one or more other embodiments of the present disclosure.

FIG. 20 is a waveform diagram illustrating an input/output signal of a stage in a display device according to one or more other embodiments of the present disclosure.

FIG. 21 is a waveform diagram illustrating a gap between a carry-out signal and a gate output signal according to a first threshold voltage of a third transistor in a display device according to one or more other embodiments of the present disclosure.

FIG. 22 is a waveform diagram illustrating a gap between a carry-out signal and a gate output signal according to a second threshold voltage of a third transistor in a display device according to one or more other embodiments of the present disclosure.

FIG. 23 is a graph illustrating a propagation delay of a gate output signal according to a first threshold voltage of a third transistor in a display device according to one or more other embodiments of the present disclosure.

FIG. 24 is a graph illustrating a propagation delay of a gate output signal according to a second threshold voltage of a third transistor in a display device according to one or more other embodiments of the present disclosure.

### DETAILED DESCRIPTION

Hereinafter, embodiments of the disclosure will be described with reference to the drawings. In this specification, when it is mentioned that a component (or, an area, a layer, a part, etc.) is referred to as being “on”, “connected to” or “combined to” another component, this means that the component may be directly on, connected to, or combined to the other component or a third component therebetween may be present.

Like reference numerals refer to like elements. Additionally, in the drawings, the thicknesses, proportions, and dimensions of components are exaggerated for effective description. “And/or” includes all of one or more combinations defined by related components.

It will be understood that when the terms “first” and “second” are used herein to describe various components, these components should not be limited by these terms. The above terms are used only to distinguish one component from another. For example, a first component may be referred to as a second component and vice versa without departing from the scope of the present disclosure. Singular expressions and terms used herein also encompass or include plural expressions and terms, unless the context clearly indicates otherwise.

In addition, terms such as “below”, “the lower side”, “on”, and “the upper side” are used to describe relationships or configurations of elements shown in the drawing. Such terms are understood to provide relative descriptions based on one or more directions shown in the drawing.

In various embodiments of the present disclosure, the terms “include,” “comprise,” “including,” or “comprising,” may refer to a property, a region, a fixed number, a step, a process, an element and/or a component, but do not exclude other properties, regions, fixed numbers, steps, processes, elements and/or components.

In the following description, when a detailed description of well-known functions or configurations related to this document is determined to unnecessarily cloud a gist of the inventive concept, the detailed description thereof will be omitted or may be briefly discussed.

Any implementation described herein as an “example” is not necessarily to be construed as preferred or advantageous over other implementations.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

In describing a temporal relationship, when the temporal order is described as, for example, “after,” “subsequent,” “next,” and “before,” a case that is not continuous may be included unless a more limiting term, such as “just,” “immediate(ly),” or “direct(ly)” is used.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

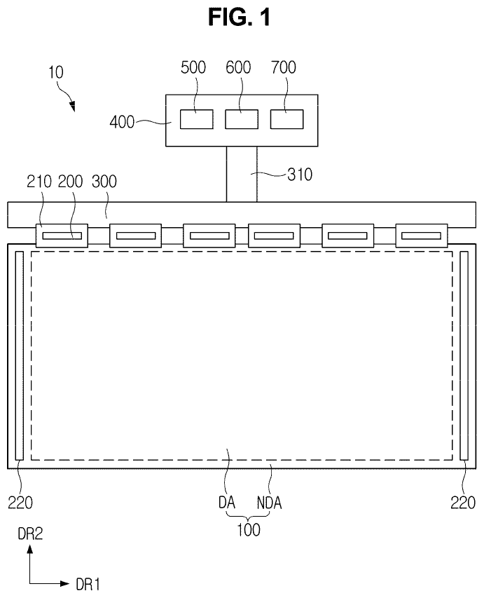

FIG. 1 is a plan view illustrating a display device according to one or more embodiments of the present disclosure.

Referring to FIG. 1, the display device 10 may be applied to a portable electronic device such as a mobile phone, a smart phone, a tablet personal computer, a mobile communication terminal, an electronic organizer, an e-book reader, a portable multimedia player (PMP), a navigation apparatus, an ultra-mobile PC (UMPC), and the like. For example, the display device 10 according to the present embodiment may be applied as a display unit of a television, a notebook computer, a monitor, a billboard, an Internet of things (IoT) device, and the like. As another example, the display device 10 according to one or more embodiments may be applied to various wearable devices, for example, such as smart watches, watch phones, glass-like displays, head-mounted displays (HMDs), and the like.

The display device 10 may include a display panel 100, a display driver 200, a flexible film 210, a source circuit board 300, a flexible cable 310, a control circuit board 400, a timing controller 500, a power supply unit 600, and a memory 700.

The display panel 100 may include a display region DA and a non-display region NDA. The display region DA may include a plurality of pixels SP configured to display an image. Each of the plurality of pixels may emit light from a light emitting region or an opening region. For example, the pixel may include a pixel circuit including switching elements, a pixel defining layer defining the light emitting region, and a self-light emitting element.

For example, the self-light emitting element may include at least one among an organic light emitting diode including an organic light emitting layer, a quantum-dot light emitting diode (LED) including a quantum-dot light emitting layer, an inorganic light emitting diode (LED) including an inorganic semiconductor, and a micro-light emitting diode (LED) or a nano-light emitting diode (LED), but is not limited thereto.

The display driver 200 may supply a data voltage to the data line DL of the display panel 100. The display driver 200 may be electrically connected to the flexible film 210, and to the data line DL of the display panel 100 through a pad part of the display panel 100. The display driver 200 may be formed as an integrated circuit (IC). For example, the display driver 200 may be attached to one surface of the flexible film 210 in a chip-on-film (COF) manner. The flexible film 210 may include lines electrically connecting the display driver 200 and the display panel 100. One side of the flexible film 210 may be electrically connected to the pad part of the display panel 100, and the other side of the flexible film 210 may be electrically connected to the source circuit board 300.

The source circuit board 300 may electrically connect the control circuit board 400 and the flexible film 210 to each other. The source circuit board 300 may be a printed circuit board which includes lines electrically connecting the display driver 200 and other devices to one another. The source circuit board 300 may be electrically connected to the control circuit board 400 through the flexible cable 310. For example, the flexible cable 310 may be a flexible flat cable (FFC), but is not limited thereto.

The control circuit board 400 may be a printed circuit board in which the timing controller 500, the power supply unit 600, and the memory 700 are mounted. The control circuit board 400 may mount control components and various electronic devices therein, without limitation to the drawing of FIG. 1.

The timing controller 500 may be attached to one surface of the control circuit board 400. The timing controller 500 may control the operation timing of the display driver 200 by transmitting digital video data to the display driver 200.

Here, the power supply unit 600 may generate the power supply voltage and supply the power supply voltage to the display panel 100. Here, the power supply voltage may include a first driving voltage EVDD, a second driving voltage EVSS, an initialization voltage Vint, a reference voltage Vref, and a bias voltage Vbias, but is not limited thereto.

The memory 700 may store sensing information of the pixels. For example, the memory 700 may store information on a threshold voltage of the transistor received from the display driver 200, and supply the threshold voltage information to the timing controller 500.

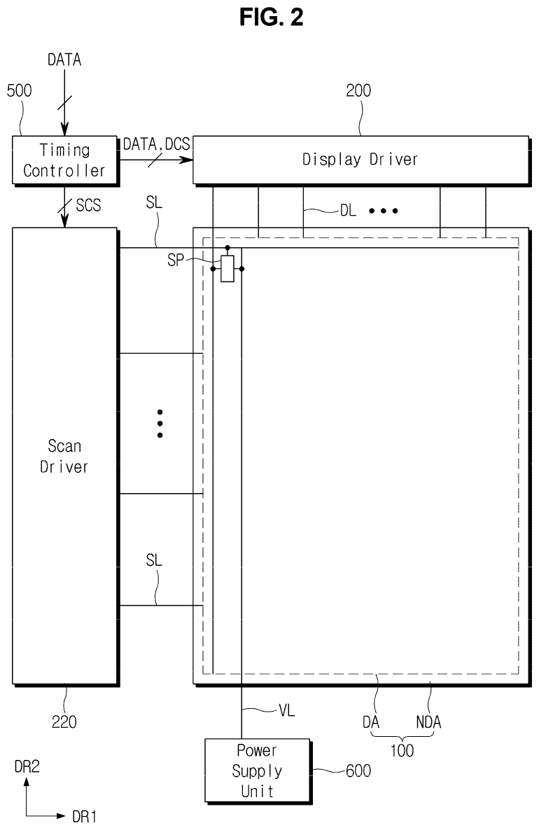

FIG. 2 is a block diagram illustrating the display device according to one or more embodiments of the present disclosure.

Referring to FIG. 2, the display panel 100 may include a display region DA and a non-display region NDA. The display region DA may include a plurality of pixels SP, a power supply line VL, a scan line SL, and a data line DL connected to the pixel SP.

Each of the pixels SP may be connected to the scan line SL, the data line DL, and the power supply line VL. Each of the pixels SP may include a transistor, a light emitting diode, and a capacitor.

The scan lines SL may extend in a first direction DR1, and may be spaced from each other in a second direction DR2 intersecting the first direction DR1. The scan lines SL may sequentially supply the scan signals to the plurality of pixels SP.

The data lines DL may extend in the second direction DR2, and may be spaced from each other in the first direction DR1. The data lines DL may supply the data voltage to the pixels SP. The data voltage may determine luminance of the pixel SP.

The power supply lines VL may extend in the second direction DR2, and may be spaced apart from each other in the first direction. The power supply lines VL may supply a power supply voltage to the plurality of pixels SP. The power supply voltage may include the first driving voltage EVDD, the second driving voltage EVSS, the initialization voltage Vint, the reference voltage Vref, and the bias voltage Vbias, but is not limited thereto.

The scan driver 220 may include a plurality of transistors, and may generate scan signals based on a scan control signal SCS. The scan driver 220 may shift a scan signal using a shift register, and may sequentially supply the shifted scan signals to the scan lines. The scan signals of the scan driver 220 may select the pixels SP to which the data voltage is supplied, and the selected pixels SP may receive the data voltage through the data lines DL. The scan driver 220 may be disposed on one side or both sides of the non-display region DNA in a Gate-In-Panel (GIP) manner.

The timing controller 500 may receive digital video data DATA and timing signals from a display driving system or a graphic device (not illustrated). The timing controller 500 may generate the data control signal DCS based on the timing signals. The timing controller 500 may supply the digital video data DATA and the data control signal DCS to the display driver 200 to control an operation timing of the display driver 200. The display driver 200 may convert the digital video data DATA into the analog data voltages and supply the analog data voltages to the data lines DL. The timing controller 500 may generate the scan control signal SCS based on the timing signals. The timing controller 500 may supply the scan control signal SCS to the scan driver 220 to control an operation timing of the scan driver 220.

The power supply unit 600 may supply a power supply voltage to the power supply lines VL. The power supply voltage may include the first driving voltage EVDD, the second driving voltage EVSS, the initialization voltage Vint, the reference voltage Vref, and the bias voltage Vbias, but is not limited thereto. The power supply unit 600 may generate the first driving voltage EVDD and supply the first driving voltage EVDD to a driving voltage line, generate the initialization voltage Vint and supply the initialization voltage Vint to an initialization voltage line, generate the bias voltage Vbias and supply the bias voltage Vbias to a bias voltage line, generate the reference voltage Vref and supply the reference voltage Vref to a reference voltage line, and generate the second driving voltage EVSS and supply the second driving voltage EVSS to a second driving voltage line.

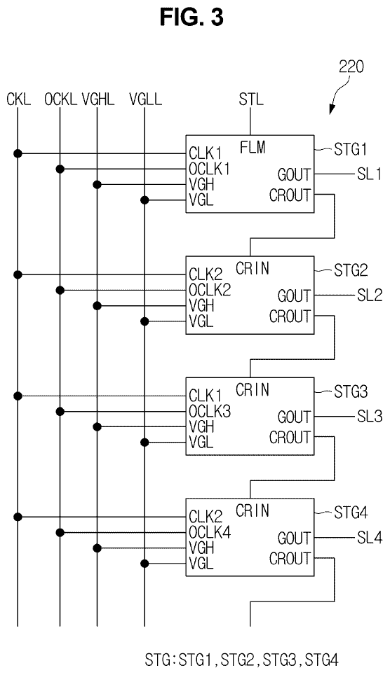

FIG. 3 is a block diagram illustrating a scan driver of the display device according to one or more embodiments of the present disclosure.

Referring to FIG. 3, the scan driver 220 may include a plurality of stages STG. A clock line CKL may supply first and second clock signals CLK1 and CLK2 to the stages STG. An output clock line OCKL may supply first to fourth output clock signals OCLK1, OCLK2, OCLK3, and OCLK4 to the stages STG. A gate high voltage line VGHL may supply a gate high voltage VGH to the stages STG, and a gate low voltage line VGLL may supply a gate low voltage VGL to the stages STG. The stages STG may generate the scan signals and supply the scan signals to the scan line SL. A gate output signal of the stages STG may correspond to a scan signal. The stages STG may include first to fourth stages STG1, STG2, STG3, and STG4.

The first stage STG1 may be connected to a start line STL, and may receive a start signal FLM. The first stage STG1 may receive a first clock signal CLK1, a first output clock signal OCLK1, the gate high voltage VGH, and the gate low voltage VGL, and may supply a first scan signal to the first scan line SL1. The first stage STG1 may supply the carry-out signal CROUT to the second stage STG2.

The carry-out signal CROUT of the first stage STG1 may be a carry-in signal CRIN which is applied to the second stage STG2. The second stage STG2 may receive the carry-in signal CRIN from the first stage STG1. The second stage STG2 may receive a second clock signal CLK2, a second output clock signal OCLK2, the gate high voltage VGH, and the gate low voltage VGL and supply a second scan signal to a second scan line SL2. The second stage STG2 may supply the carry-out signal CROUT to the third stage STG3.

The carry-out signal CROUT of the second stage STG2 may be the carry-in signal CRIN applied to the third stage STG3. The third stage STG3 may receive the carry-in signal CRIN from the second stage STG2. The third stage STG3 may receive the first clock signal CLK1, a third output clock signal OCLK3, the gate high voltage VGH, and the gate low voltage VGL and supply a third scan signal to a third scan line SL3.

The carry-out signal CROUT of the third stage STG3 may be the carry-in signal CRIN applied to the fourth stage STG4. The fourth stage STG4 may receive the carry-in signal CRIN from the third stage STG3. The fourth stage STG4 may receive the second clock signal CLK2, a fourth output clock signal OCLK4, the gate high voltage VGH, and the gate low voltage VGL and supply a fourth scan signal to the fourth scan line SL4.

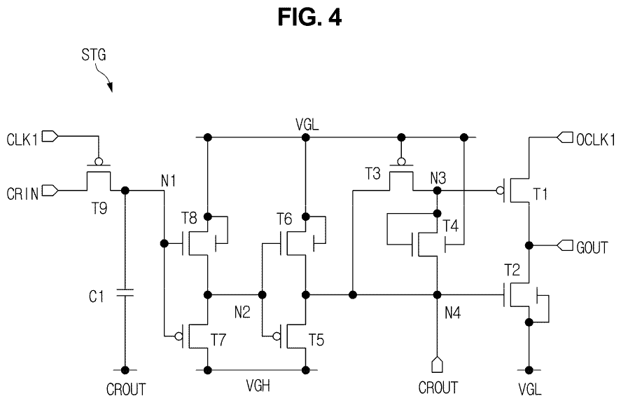

FIG. 4 is a circuit diagram illustrating the stage of the scan driver in the display device according to one or more embodiments of the present disclosure.

Referring to FIG. 4, the stage STG may include first to ninth transistors T1, T2, T3, T4, T5, T6, T7, T8, and T9 and a first capacitor C1.

The first transistor T1 may receive the first output clock signal OCLK1 based on a voltage of a third node N3 and may output a gate output signal GOUT. Here, the third node N3 may be connected to a gate electrode of the first transistor T1, a drain electrode of the third transistor T3, a drain electrode and a gate electrode of the fourth transistor T4. The gate electrode of the first transistor T1 may be connected to the third node N3, a source electrode of the first transistor T1 may receive the first output clock signal OCLK1, and a drain electrode of the first transistor T1 may output the gate output signal GOUT.

The second transistor T2 may discharge the gate output signal GOUT to the gate low voltage VGL based on a voltage of a fourth node N4. Here, the fourth node N4 may output the carry-out signal CROUT, and may be connected to a gate electrode of the second transistor T2, a source electrode of the third transistor T3, a source electrode of the fourth transistor T4, a drain electrode of the fifth transistor T5, and a drain electrode of the sixth transistor T6. The gate electrode of the second transistor T2 may be connected to the fourth node N4, a drain electrode of the second transistor T2 may receive the gate output signal GOUT, and a source electrode of the second transistor T2 may receive the gate low voltage VGL. The second transistor T2 may further include a bias electrode overlapping the gate electrode, or a bottom gate electrode. The bias electrode of the second transistor T2 may receive the gate low voltage VGL.

The third transistor T3 may supply a voltage of the fourth node N4 to the third node N3 based on the gate low voltage VGL. A gate electrode of the third transistor T3 may receive the gate low voltage VGL, the source electrode of the third transistor T3 may be connected to the fourth node N4, and a drain electrode of the third transistor T3 may be connected to the third node N3.

The fourth transistor T4 may be diode-connected between the third node N3 and the fourth node N4. The fourth transistor T4 may supply a voltage of the third node N3 to the fourth node N4 based on the voltage of the third node N3. A gate electrode and a drain electrode of the fourth transistor T4 may be connected to the third node N3, a source electrode of the fourth transistor T4 may be connected to the fourth node N4. The fourth transistor T4 may further include a bias electrode overlapping the gate electrode, or a bottom gate electrode. A bias electrode of the fourth transistor T4 may receive the gate low voltage VGL.

The fifth transistor T5 may supply the gate high voltage VGH to the fourth node N4 based on a voltage of the second node N2. Here, the second node N2 may be connected to a gate electrode of the fifth transistor T5, a gate electrode of the sixth transistor T6, a drain electrode of the seventh transistor T7, and a drain electrode of the eighth transistor T8. The gate electrode of the fifth transistor T5 may be connected to the second node N2, a source electrode of the fifth transistor T5 may receive the gate high voltage VGH, and the drain electrode of the fifth transistor T5 may be connected to the fourth node N4.

The sixth transistor T6 may discharge the voltage of the fourth node N4 to the gate low voltage VGL based on the voltage of the second node N2. The gate electrode of the sixth transistor T6 may be connected to the second node N2, the drain electrode of the sixth transistor T6 may be connected to the fourth node N4, and a source electrode of the sixth transistor T6 may receive the gate low voltage VGL. The sixth transistor T6 may further include a bias electrode overlapping the gate electrode, or a bottom gate electrode. A bias electrode of the sixth transistor T6 may receive the gate low voltage VGL.

The seventh transistor T7 may supply the gate high voltage VGH to the second node N2 based on the voltage of the first node N1. Here, the first node N1 may be connected to a gate electrode of the seventh transistor T7, a gate electrode of the eighth transistor T8, a drain electrode of the ninth transistor T9, and a first capacitor electrode of the first capacitor C1. The gate electrode of the seventh transistor T7 may be connected to the first node N1, a source electrode of the seventh transistor T7 may receive the gate high voltage VGH, and the drain electrode of the seventh transistor T7 may be connected to the second node N2.

The eighth transistor T8 may discharge the voltage of the second node N2 to the gate low voltage VGL based on the voltage of the first node N1. The gate electrode of the eighth transistor T8 may be connected to the first node N1, the drain electrode of the eighth transistor T8 may be connected to the second node N2, and a source electrode of the eighth transistor T8 may receive the gate low voltage VGL. The eighth transistor T8 may further include a bias electrode overlapping the gate electrode, or a bottom gate electrode. A bias electrode of the eighth transistor T8 may receive the gate low voltage VGL.

The ninth transistor T9 may supply the carry-in signal CRIN to the first node N1 based on the first clock signal CLK1. The carry-in signal CRIN received by the stage STG in FIG. 4 may be the carry-out signal CROUT of a previous stage. The ninth transistor T9 of a next stage of the stage STG in FIG. 4 may supply the carry-in signal CRIN to the first node N1 based on the second clock signal CLK2. A gate electrode of the ninth transistor T9 may receive the first clock signal CLK1, a source electrode of the ninth transistor T9 may receive the carry-in signal CRIN, and a drain electrode of the ninth transistor T9 may be connected to the first node N1.

The first capacitor C1 may be connected between the first node N1 and the carry-out signal CROUT, and may maintain a potential difference between the first node N1 and the carry-out signal CROUT.

The first transistor T1, the third transistor T3, the fifth transistor T5, the seventh transistor T7, and the ninth transistor T9 may include a silicon-based semiconductor region. For example, the first transistor T1, the third transistor T3, the fifth transistor T5, the seventh transistor T7, and the ninth transistor T9 may include a semiconductor region formed of the Low Temperature Polycrystalline Silicon (LTPS). The semiconductor region formed of the Low Temperature Polycrystalline Silicon (LTPS) has a high electron mobility, and an excellent turn-on characteristic. Therefore, as the display device 10 includes the first transistor T1, the third transistor T3, the fifth transistor T5, the seventh transistor T7, and the ninth transistor T9 having an excellent turn-on characteristic, the display device 10 may drive the scan driver 220 stably and efficiently.

The first transistor T1, the third transistor T3, the fifth transistor T5, the seventh transistor T7, and the ninth transistor T9 may be p-type transistors. For example, the first transistor T1, the third transistor T3, the fifth transistor T5, the seventh transistor T7, and the ninth transistor T9 may output a current introduced into the first electrode to the second electrode based on the gate low voltage VGL which is applied to the gate electrode. A first electrode of each of the first transistor T1, the third transistor T3, the fifth transistor T5, the seventh transistor T7, and the ninth transistor T9 may be a source electrode, and a second electrode of each thereof may be a drain electrode.

The second transistor T2, the fourth transistor T4, the sixth transistor T6, and the eighth transistor T8 may include an oxide-based semiconductor region. For example, the second transistor T2, the fourth transistor T4, the sixth transistor T6, and the eighth transistor T8 may have a coplanar structure in which a gate electrode is disposed on an upper portion of the oxide-based semiconductor region. The transistor T having the coplanar structure may have an excellent leakage current characteristic and allow a low frequency driving, thereby being able to reduce the power consumption. Therefore, as the display device 10 includes the second transistor T2, the fourth transistor T4, the sixth transistor T6, and the eighth transistor T8 having the excellent leakage current characteristic, the display device 10 may prevent or reduce the leakage current from flowing in the stage STG, and may maintain a voltage inside the stage STG stably, thereby improving reliability of the scan signal.

The second transistor T2, the fourth transistor T4, the sixth transistor T6, and the eighth transistor T8 may be n-type transistors. For example, the second transistor T2, the fourth transistor T4, the sixth transistor T6, and the eighth transistor T8 may output a current introduced into the first electrode to the second electrode based on the gate high voltage VGH which is applied to the gate electrode. Here, a first electrode of each of the second transistor T2, the fourth transistor T4, the sixth transistor T6, and the eighth transistor T8 may be a drain electrode, and a second electrode of each thereof may be a source electrode.

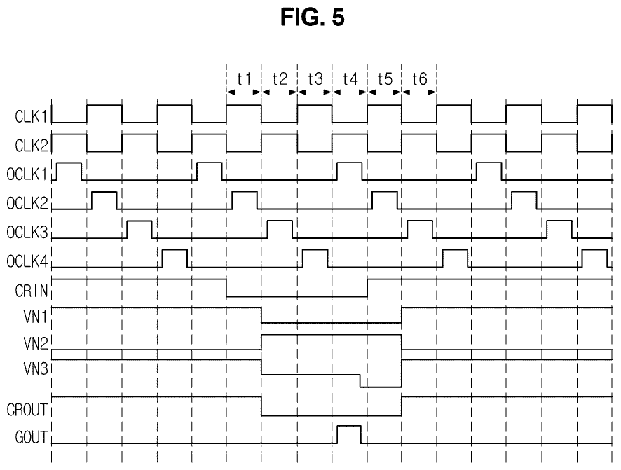

FIG. 5 is a waveform diagram illustrating an input/output signal of the stage in the display device according to one or more embodiments of the present disclosure.

Referring to FIG. 5, the clock line CKL may supply the first and second clock signals CLK1 and CLK2 to the stages STG. The first and second clock signals CLK1 and CLK2 may alternately have a high level and a low level based on a predetermined frequency. The first and second clock signals CLK1 and CLK2 may have a phase difference of 180 degrees. The first clock signal CLK1 may have a high level at a first interval t1, a third interval t3, and a fifth interval t5, and may have a low level at a second interval t2, a fourth interval t4, and a sixth interval t6. The second clock signal CLK2 may have a high level at the second interval t2, the fourth interval t4, and the sixth interval t6, and may have a low level at the first interval t1, the third interval t3, and the fifth interval t5.

The output clock line OCKL may supply the first to fourth output clock signals OCLK1, OCLK2, OCLK3, and OCLK4 to the stages STG. The first to fourth output clock signals OCLK1, OCLK2, OCLK3, and OCLK4 may sequentially have a high level. The first output clock signal OCLK1 may have a high level at the fourth interval t4. The second output clock signal OCLK2 may have a high level at the first interval t1 and the fifth interval t5. The third output clock signal OCLK3 may have a high level at the second interval t2 and the sixth interval t6. The fourth output clock signal OCLK4 may have a high level at the third interval t3.

The carry-in signal CRIN received by the stage STG may be the carry-out signal CROUT of a previous stage. The carry-out signal CROUT output from the stage STG may be the carry-in signal CRIN of the next stage. The carry-in signal CRIN may have a low level at the first to fourth intervals t1, t2, t3, and t4. The carry-out signal CROUT output from the stage STG may be a delay signal of the carry-in signal CRIN received by the stage STG. Therefore, the carry-out signal CROUT may have a low level at the second to fifth intervals t2, t3, t4, and t5.

As shown in FIG. 4, the gate electrode of the ninth transistor T9 may receive the first clock signal CLK1 in a low level at the second interval t2. The ninth transistor T9 may supply the carry-in signal CRIN to the first node N1 based on the first clock signal CLK1 in a low level. A voltage VN1 of the first node N1 may be stored in the first capacitor electrode of the first capacitor C1. Therefore, the voltage VN1 of the first node N1 may have a low level at the second to fifth intervals t2, t3, t4, and t5.

The gate electrode of the seventh transistor T7 may receive the voltage VN1 of the first node N1 in a low level at the second to fifth intervals t2, t3, t4, and t5. The seventh transistor T7 may supply the gate high voltage VGH to the second node N2 based on the voltage VN1 of the first node N1 in a low level.

The gate electrode of the eighth transistor T8 may receive the voltage VN1 of the first node N1 in a high level at the sixth interval t6. The eighth transistor T8 may discharge a voltage of the second node N2 to the gate low voltage VGL based on the voltage VN1 of the first node N1 in a high level.

The gate electrode of the sixth transistor T6 may receive the voltage VN2 of the second node N2 in a high level at the second to fifth intervals t2, t3, t4, and t5. The sixth transistor T6 may discharge a voltage of the fourth node N4 to the gate low voltage VGL based on the voltage VN2 of the second node N2 in a high level. The voltage VN4 of the fourth node N4 may be output as the carry-out signal CROUT.

The gate electrode of the fifth transistor T5 may receive the voltage VN2 of the second node N2 in a low level at the sixth interval t6. The fifth transistor T5 may supply the gate high voltage VGH to the fourth node N4 based on the voltage VN2 of the second node N2 in a low level. Therefore, the carry-out signal CROUT may have a low level at the second to fifth intervals t2, t3, t4, and t5, and may have a high level from the sixth interval t6.

The third transistor T3 may maintain a turn-on state at the first to sixth intervals t1, t2, t3, t4, t5, and t6 based on the gate low voltage VGL. The third transistor T3 may supply the voltage of the fourth node N4 to the third node N3. Therefore, a voltage VN3 of the third node N3 may have a first low level at the second to fourth intervals t2, t3, and t4.

The first transistor T1 may receive the first output clock signal OCLK1 based on the voltage VN3 of the third node N3, and may output the gate output signal GOUT. The first output clock signal OCLK1 may have a high level at the fourth interval t4, and may have a low level from the fifth interval t5. The second transistor T2 may receive the voltage of the fourth node N4 in a high level at the sixth interval t6. The second transistor T2 may discharge the gate output signal GOUT to the gate low voltage VGL based on the voltage of the fourth node N4 in a high level. Therefore, the gate output signal GOUT may have a high level at the fourth interval t4, and may have a low level from the fifth interval t5. The second transistor T2 may reduce a fall time of the gate output signal GOUT.

As the voltage VN3 of the third node N3 is bootstrapped by a falling edge of the gate output signal GOUT, the voltage VN3 of the third node N3 may have a second low level, which is lower than the first low level, at the fifth interval t5. Here, the second low level of the voltage VN3 of the third node N3 may be lower than the gate low voltage VGL. As the fourth transistor T4 is diode-connected between the third node N3 and the fourth node N4, the fourth transistor T4 may prevent or reduce the voltage VN3 of the third node N3 from being delivered to the fourth node N4. Therefore, the carry-out signal CROUT may maintain a low level at the fifth interval t5, without being influenced by the voltage VN3 of the third node N3.

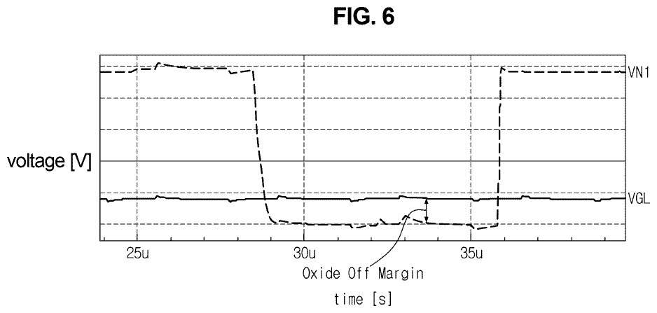

FIG. 6 is a waveform diagram illustrating an example of an off-margin of the eighth transistor in the display device according to one or more embodiments of the present disclosure.

Referring to FIG. 6, the ninth transistor T9 may supply the carry-in signal CRIN to the first node N1 based on the first clock signal CLK1. As shown in FIGS. 4 and 5, the gate electrode of the ninth transistor T9 may receive the first clock signal CLK1 in a low level at the second interval t2. The ninth transistor T9 may supply the carry-in signal CRIN to the first node N1 based on the first clock signal CLK1 in a low level. The voltage VN1 of the first node N1 may be stored in the first capacitor electrode of the first capacitor C1. The voltage VN1 of the first node N1 may have a low level at the second to fifth intervals t2, t3, t4, and t5. Here, 29[μs] to 36[μs] shown in FIG. 6 may correspond to the second to fifth intervals t2, t3, t4, and t5. The voltage VN1 of the first node N1 may be lower than the gate low voltage VGL. A voltage difference in a low level between the gate low voltage VGL and the voltage VN1 of the first node N1 may correspond to an oxide off-margin of the eighth transistor T8. The stage STG may expand the oxide off-margin of the eighth transistor T8 by storing the voltage VN1 of the first node N1 in the first capacitor C1 at the second to fifth intervals t2, t3, t4, and t5.

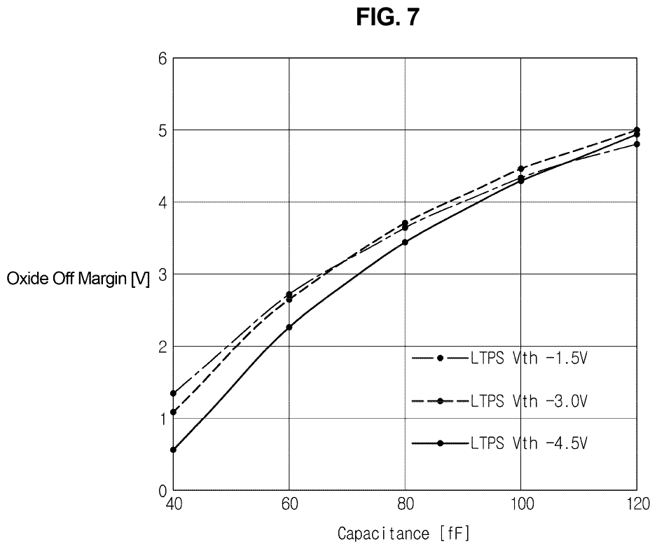

FIG. 7 is a graph illustrating the off-margin of the eighth transistor according to a capacitance of the first capacitor in the display device according to one or more embodiments of the present disclosure. As shown in FIGS. 4 and 7, the ninth transistor T9 may include a semiconductor region formed of the Low Temperature Polycrystalline Silicon (LTPS), and may have a threshold voltage Vth of −1.5[V], −3.0[V], or −4.5[V].

Referring to FIG. 7, the oxide off-margin of the eighth transistor T8 may be changed according to the capacitance of the first capacitor C1 and the threshold voltage Vth of the ninth transistor T9. As the capacitance of the first capacitor C1 increases, the oxide off-margin of the eighth transistor T8 may increase. The oxide off-margin of the eighth transistor T8 may be changed according to the threshold voltage Vth of the ninth transistor T9.

For example, in a condition in which the capacitance of the first capacitor C1 is 40[fF], the oxide off-margin of the eighth transistor T8 may be higher in a case in which the threshold voltage Vth of the ninth transistor T9 is −1.5[V] than a case in which the threshold voltage Vth of the ninth transistor T9 is −3.0[V]. In a condition in which the capacitance of the first capacitor C1 is 40[fF], the oxide off-margin of the eighth transistor T8 may be higher in a case in which the threshold voltage Vth of the ninth transistor T9 is −3.0[V] than a case in which the threshold voltage Vth of the ninth transistor T9 is −4.5[V].

In a condition in which the capacitance of the first capacitor C1 is 120[fF], the oxide off-margin of the eighth transistor T8 may be higher in a case in which the threshold voltage Vth of the ninth transistor T9 is −3.0[V] than a case in which the threshold voltage Vth of the ninth transistor T9 is −4.5[V]. In a condition in which the capacitance of the first capacitor C1 is 120[fF], the oxide off-margin of the eighth transistor T8 may be higher in a case in which the threshold voltage Vth of the ninth transistor T9 is −4.5[V] than a case in which the threshold voltage Vth of the ninth transistor T9 is −1.5[V].

As an area of the first capacitor C1 increases, the capacitance of the first capacitor C1 may increase more, however, the area of the first capacitor C1 may be limited by a design area of the layout. For example, in a condition in which the capacitance of the first capacitor C1 is 80[fF], the area of the first capacitor C1 may be adjusted to an allowable level while the oxide off-margin of the eighth transistor T8 has a relatively high value, however, the capacitance value of the first capacitor C1 is not limited thereto.

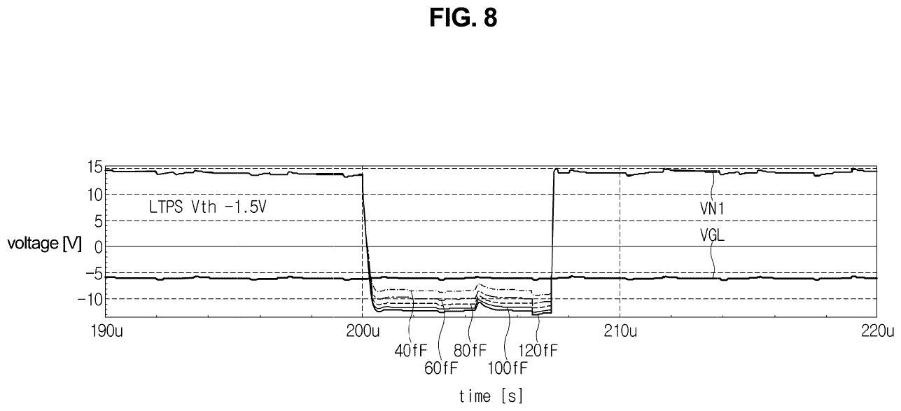

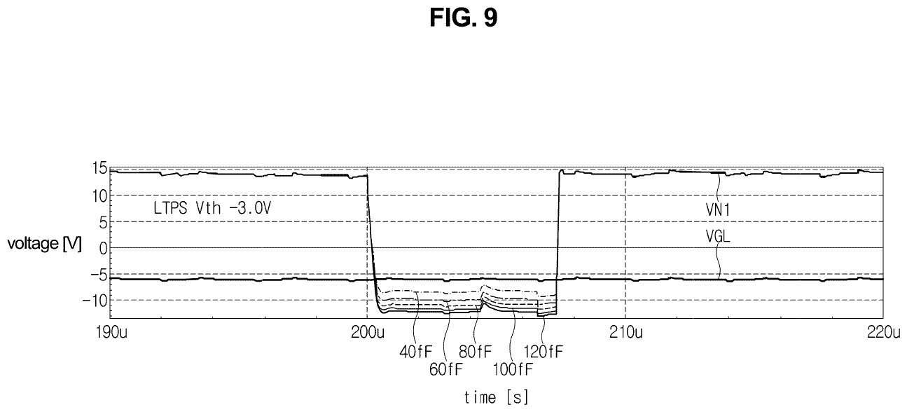

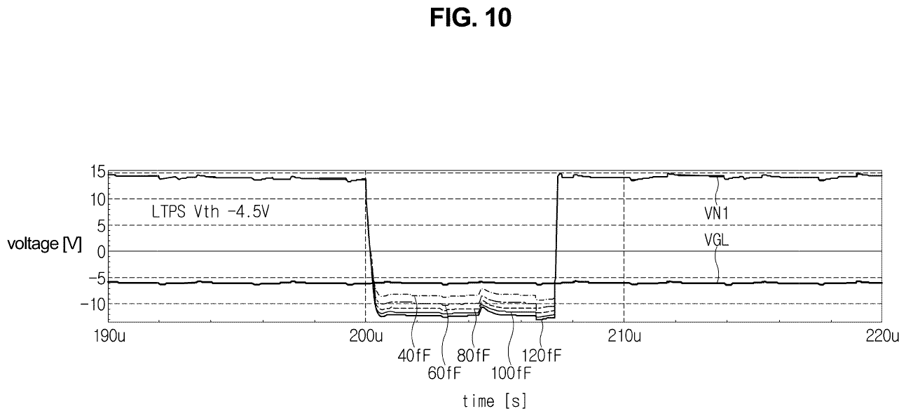

FIG. 8 is a graph illustrating an example of the off-margin of the eighth transistor according to the capacitance of the first capacitor in the display device according to one or more embodiments of the present disclosure, FIG. 9 is a graph illustrating another example of the off-margin of the eighth transistor according to the capacitance of the first capacitor in the display device according to one or more embodiments of the present disclosure, and FIG. 10 is a graph illustrating still another example of the off-margin of the eighth transistor according to the capacitance of the first capacitor in the display device according to one or more embodiments of the present disclosure.

FIG. 8 shows the voltage of the first node N1 according to the capacitance of the first capacitor C1 in a case in which the threshold voltage Vth of the ninth transistor T9 is −1.5[V]. FIG. 9 shows the voltage of the first node N1 according to the capacitance of the first capacitor C1 in a case in which the threshold voltage Vth of the ninth transistor T9 is −3.0[V]. FIG. 10 shows the voltage of the first node N1 according to the capacitance of the first capacitor C1 in a case in which the threshold voltage Vth of the ninth transistor T9 is −4.5[V].

In FIG. 8, in a case in which the threshold voltage Vth of the ninth transistor T9 is −1.5[V], as the capacitance of the first capacitor C1 increases, the voltage VN1 of the first node N1 may have a relatively lower level, and the oxide off-margin of the eighth transistor T8 may increase.

In FIG. 9, in a case in which the threshold voltage Vth of the ninth transistor T9 is −3.0[V], as the capacitance of the first capacitor C1 increases, the voltage VN1 of the first node N1 may have a relatively lower level, and the oxide off-margin of the eighth transistor T8 may increase.

In FIG. 10, in a case in which the threshold voltage Vth of the ninth transistor T9 is −4.5[V], as the capacitance of the first capacitor C1 increases, the voltage VN1 of the first node N1 may have a relatively lower level, and the oxide off-margin of the eighth transistor T8 may increase.

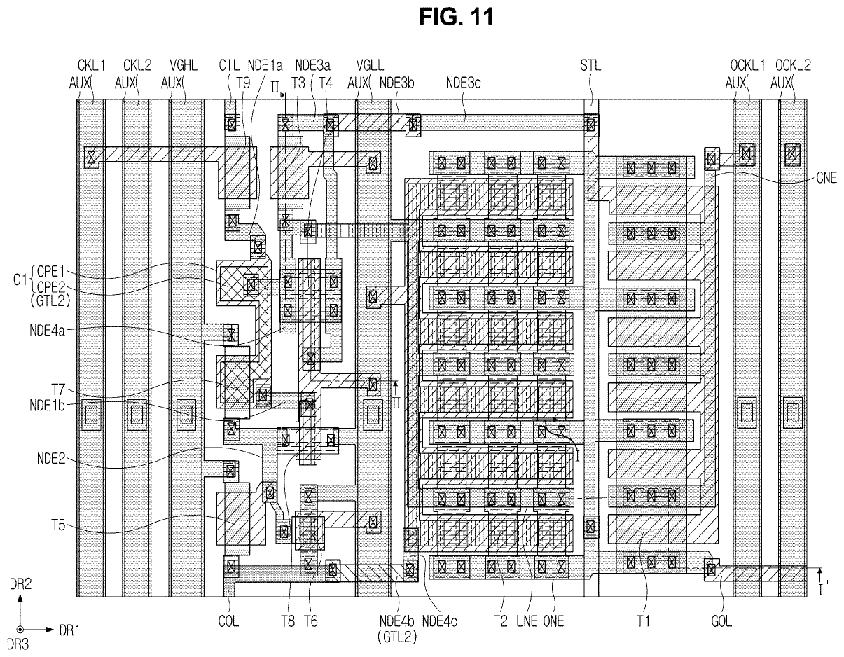

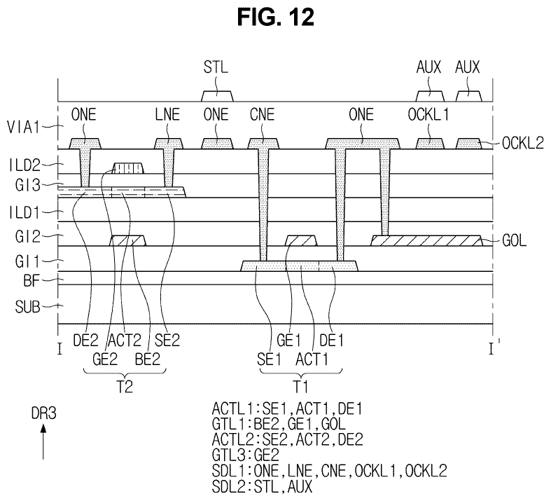

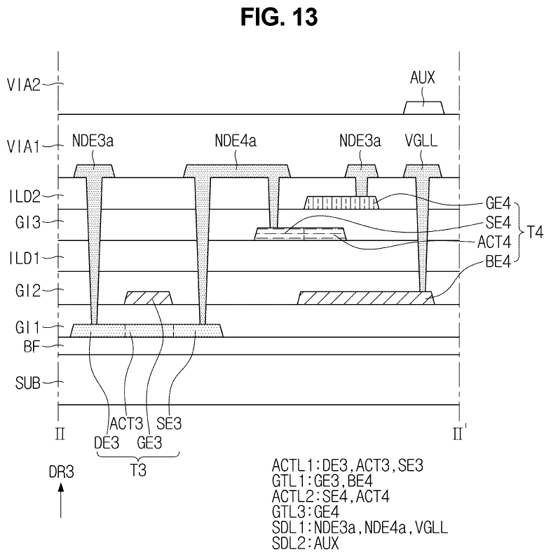

FIG. 11 is a layout diagram illustrating the stage of the display device according to one or more embodiments of the present disclosure, FIG. 12 is a cross-sectional view taken along I-I′ line in FIG. 11, and FIG. 13 is a cross-sectional view taken along II-II′ line in FIG. 11.

Referring to FIGS. 11 to 13, the stage STG may include a substrate SUB, a buffer layer BF, a first active layer ACTL1, a first gate insulation layer GI1, a first gate layer GTL1, a second gate insulation layer GI2, a second gate layer GTL2, a first inter-layer insulation layer ILD1, a second active layer ACTL2, a third gate insulation layer GI3, a third gate layer GTL3, a second inter-layer insulation layer IDL2, a first source metal layer SDL1, a first via layer VIA1, a second source metal layer SDL2, and a second via layer VIA2, which are sequentially laminated. The stage STG may include the first to ninth transistors T1, T2, T3, T4, T5, T6, T7, T8, and T9 and the first capacitor C1.

The first clock line CKL1 may be disposed in the first source metal layer SDL1, and may extend in the second direction DR2. The first clock line CKL1 may overlap an auxiliary line AUX disposed in the second source metal layer SDL2 and may be electrically connected to the auxiliary line AUX. The first clock line CKL1 may reduce a line resistance because the first clock line CKL1 is connected to the auxiliary line AUX. The first clock line CKL1 may be connected to the gate electrode of the ninth transistor T9 disposed in the first gate layer GTL1, and may supply the first clock signal CLK1 to the gate electrode of the ninth transistor T9. The gate electrode of the ninth transistor T9 may extend in the first direction DR1, and may intersect the second clock line CKL2 and the gate high voltage line VGHL.

The second clock line CKL2 may be disposed in the first source metal layer SDL1, and may extend in the second direction DR2. The second clock line CKL2 may be disposed in the first direction DR1 of the first clock line CKL1. The second clock line CKL2 may overlap the auxiliary line AUX disposed in the second source metal layer SDL2 and may be electrically connected to the auxiliary line AUX. The second clock line CKL2 may reduce a line resistance because the second clock line CK2 is connected to the auxiliary line AUX. The second clock line CKL2 may supply the second clock signal CLK2 to the next stage.

The gate high voltage line VGHL may be disposed in the first source metal layer SDL1 and may extend in the second direction DR2. The gate high voltage line VGHL may be disposed in the first direction DR1 of the second clock line CKL2. The gate high voltage line VGHL may overlap the auxiliary line AUX disposed in the second source metal layer SDL2 and may be electrically connected to the auxiliary line AUX. The second clock line CKL2 may reduce a line resistance because the second clock line CK2 is connected to the auxiliary line AUX. The gate high voltage line VGHL may include a first portion and a second portion protruding in the first direction DR1. A first portion of the gate high voltage line VGHL may be connected to the source electrode of the fifth transistor T5 disposed in the first active layer ACTL1. A second portion of the gate high voltage line VGHL may be connected to the source electrode of the seventh transistor T7 disposed in the first active layer ACTL1. Therefore, the gate high voltage line VGHL may supply the gate high voltage VGH to each of the source electrodes of the fifth and seventh transistors T5 and T7.

The gate low voltage line VGLL may be disposed in the first source metal layer SDL1 and may extend in the second direction DR2. The gate low voltage line VGLL may be disposed in a direction opposite the first direction DR1 of the second clock line CKL2. The gate low voltage line VGLL may overlap the auxiliary line AUX disposed in the second source metal layer SDL2 and may be electrically connected to the auxiliary line AUX. The second clock line CKL2 may reduce a line resistance because the second clock line CK2 is connected to the auxiliary line AUX. The gate low voltage line VGLL may include a first portion protruding in the first direction DR1, a second portion and a third portion protruding in a direction opposite the first direction DR1. The first portion of the gate low voltage line VGLL may be connected to a source electrode SE2 of the second transistor T2 disposed in the first active layer ACTL1. The second portion of the gate low voltage line VGLL may be connected to the source electrode of the sixth transistor T6 disposed in the second active layer ACTL2. The third portion of the gate low voltage line VGLL may be connected to the source electrode of the eighth transistor T8 disposed in the second active layer ACTL2. The gate low voltage line VGLL may be connected to the bias electrodes of the second, fourth, sixth, and eighth transistors T2, T4, T6, and T8 disposed in the first gate layer GTL1. Therefore, the gate low voltage line VGLL may supply the gate low voltage VGL to the source electrode of each of the second, sixth, and eighth transistors T2, T6, and T8, and to the bias electrode of each of the second, fourth, sixth, and eighth transistors T2, T4, T6, and T8.

A first output clock line OCKL1 may be disposed in the first source metal layer SDL1 and may extend in the second direction DR2. The first output clock line OCKL1 may be disposed in the first direction DR1 of the first transistor T1. The first output clock line OCKL1 may overlap the auxiliary line AUX disposed in the second source metal layer SDL2 and may be electrically connected to the auxiliary line AUX. The first output clock line OCKL1 may reduce a line resistance because the first output clock line OCKL1 is connected to the auxiliary line AUX. The first output clock line OCKL1 may be electrically connected to the source electrode SE1 of the first transistor T1 disposed in the first active layer ACTL1 through a clock connection electrode CNE disposed in the first source metal layer SDL1. The clock connection electrode CNE may include a plurality of branch portions protruding in a direction opposite the first direction DR1. Each of the plurality of branch portions of the clock connection electrode CNE may be connected to a plurality of source electrodes SE1 of the first transistor T1, respectively. Therefore, the first output clock line OCKL1 may supply the first output clock signal OCLK1 to the source electrode SE1 of the first transistor T1.

A second output clock signal OCLK2 may be disposed in the first source metal layer SDL1 and may extend in the second direction DR2. The second output clock signal OCLK2 may be disposed in the first direction DR1 of the first output clock line OCKL1. The second output clock signal OCLK2 may overlap the auxiliary line AUX disposed in the second source metal layer SDL2 and may be electrically connected to the auxiliary line AUX. The second output clock signal OCLK2 may reduce a line resistance because the second output clock line OCKL2 is connected to the auxiliary line AUX. The second output clock line OCKL2 may supply the second output clock signal OCLK2 to the next stage.

A start line STL may be disposed in the second source metal layer SDL2 and may extend in the second direction DR2. As shown in FIG. 3, the start line STL may supply the start signal FLM to the first stage STG1 among the plurality of stages STG.

The first transistor T1 may include the semiconductor region ACT1, the gate electrode GE1, the source electrode SE1, and the drain electrode DE1. The semiconductor region ACT1, the source electrode SE1, and the drain electrode DE1 of the first transistor T1 may be disposed in the first active layer ACTL1, and the gate electrode GE1 of the first transistor T1 may be disposed in the first gate layer GTL1. The gate electrode GE1 of the first transistor T1 may include a stem portion extending in the second direction DR2, and a plurality of branch portions extending in the direction opposite the first direction DR1. Each of the plurality of branch portions of the gate electrode GE1 of the first transistor T1 may overlap each of a plurality of semiconductor regions ACT1 of the first transistor T1 which is spaced apart from each other in the second direction DR2.

The gate electrode GE1 of the first transistor T1 may be electrically connected to the drain electrode DE3 of the third transistor T3, the gate electrode GE4 and the drain electrode of the fourth transistor T4 through a third node electrode. The third node electrode may include a first portion NDE3a, a second portion NDE3b, and a third portion NDE3c. The first portion NDE3a of the third node electrode may be disposed in the first source metal layer SDL1, and may be directly connected to the drain electrode DE3 of the third transistor T3, the gate electrode GE4 and the drain electrode of the fourth transistor T4. The second portion NDE3b of the third node electrode may be disposed in the first gate layer GTL1, and may electrically connect the first portion NDE3a and the third portion NDE3c of the third node electrode to each other. The third portion NDE3c of the third node electrode may be disposed in the first source metal layer SDL1, and may be directly connected to the gate electrode GE1 of the first transistor T1.

An output connection electrode ONE may be disposed in the first source metal layer SDL1. The output connection electrode ONE may include a stem portion extending in the second direction DR2, a plurality of first portions extending in the first direction DR1, and a plurality of second portions extending in the direction opposite the first direction DR1. Each of the plurality of first portions of the output connection electrode ONE may be connected to the plurality of drain electrodes DE1 of the first transistor T1, respectively. One among the plurality of first portions of the output connection electrode ONE may be connected to a gate output line GOL disposed in the first gate layer GTL1. Therefore, the first transistor T1 may output the gate output signal GOUT to the gate output line GOL. Each of the plurality of second portions of the output connection electrode ONE may be connected to the plurality of drain electrodes DE2 of the second transistor T2 disposed in the second active layer ACTL2, respectively.

The second transistor T2 may include the semiconductor region ACT2, the gate electrode GE2, the drain electrode DE2, and the source electrode SE2. The semiconductor region ACT2, the drain electrode DE2, and the source electrode SE2 of the second transistor T2 may be disposed in the second active layer ACTL2, and the gate electrode GE2 of the second transistor T2 may be disposed in the third gate layer GTL3. The gate electrode GE2 of the second transistor T2 may overlap the semiconductor region ACT2.

The gate electrode GE2 of the second transistor T2 may be electrically connected to a carry-out line COL disposed in the first source metal layer SDL1 through a second portion NDE4b of a fourth node electrode disposed in the second gate layer GTL2, and a third portion NED4c of the fourth node electrode disposed in the first source metal layer SDL1. The stage STG may output the carry-out signal CROUT through the carry-out line COL. The gate electrode GE2 of the second transistor T2 may be electrically connected to a second capacitor electrode CPE2 of the first capacitor C1 disposed in the second gate layer GTL2, a source electrode SE3 of the third transistor T3, and a source electrode SE4 of the fourth transistor T4. The gate electrode GE2 of the second transistor T2 may include a contact portion connected to a first portion NDE4a of the fourth node electrode and extending in the first direction DR1, and a plurality of stem portions extending in the second direction DR2, and a plurality of branch portions extending in the first direction DR1 from the stem portion. The contact portion of the gate electrode GE2 of the second transistor T2 may intersect the gate low voltage line VGLL. Each of the plurality of branch portions of the gate electrode GE2 of the second transistor T2 may overlap each of the plurality of semiconductor regions ACT2 of the second transistor T2 spaced apart from each other in the second direction DR2, respectively.

Each of the plurality of drain electrodes DE2 of the second transistor T2 may be connected to each of the plurality of second portions of the output connection electrode ONE, respectively. The source electrode SE2 of the second transistor T2 may be connected to the first portion of the gate low voltage line VGLL. The first portion of the gate low voltage line VGLL may include a stem portion extending in the second direction DR2, and a plurality of branch portions extending in the first direction DR1. Each of the plurality of branch portions of the first portion of the gate low voltage line VGLL may be connected to each of the plurality of source electrodes SE2 of the second transistor T2, respectively.

The second transistor T2 may further include the bias electrode BE2 disposed in the first gate layer GTL1. The bias electrode BE2 of the second transistor T2 may include a stem portion extending in the second direction DR2, and a plurality of branch portions extending in the first direction DR1. The stem portion of the bias electrode BE2 may be connected to the gate low voltage line VGLL, and may overlap the stem portion of the gate electrode GE2. The plurality of branch portions of the bias electrode BE2 may overlap the plurality of branch portions of the gate electrode GE2.

The third transistor T3 may include the semiconductor region ACT3, the gate electrode GE3, the source electrode SE3, and the drain electrode DE3. The semiconductor region ACT3, the source electrode SE3, and the drain electrode DE3 of the third transistor T3 may be disposed in the first active layer ACTL1, and the gate electrode GE3 of the third transistor T3 may be disposed in the first gate layer GTL1. The gate electrode GE3 of the third transistor T3 may overlap the semiconductor region ACT3. The gate electrode GE3 of the third transistor T3 may be connected to the gate low voltage line VGLL.

The source electrode SE3 of the third transistor T3 may be electrically connected to the second capacitor electrode CPE2 of the first capacitor C1, the gate electrode GE2 of the second transistor T2, and the source electrode SE4 of the fourth transistor T4 through the first portion NDE4a of the fourth node electrode. The drain electrode DE3 of the third transistor T3 may be electrically connected to the gate electrode GE1 of the first transistor T1 through the first portion NDE3a, the second portion NDE3b, and the third portion NDE3c of the third node electrode. The drain electrode DE3 of the third transistor T3 may be electrically connected to the gate electrode GE4 and the drain electrode of the fourth transistor T4 through the first portion NDE3a of the third node electrode.

The fourth transistor T4 may include the semiconductor region ACT4, the gate electrode GE4, the drain electrode DE4, and the source electrode SE4. The semiconductor region ACT4, the drain electrode DE4, and the source electrode SE4 of the fourth transistor T4 may be disposed in the second active layer ACTL2, and the gate electrode GE4 of the fourth transistor T4 may be disposed in the third gate layer GTL3. The gate electrode GE4 of the fourth transistor T4 may overlap the semiconductor region ACT4. The gate electrode GE4 and the drain electrode DE4 of the fourth transistor T4 may be electrically connected to the gate electrode GE1 of the first transistor T1 and the drain electrode DE3 of the third transistor T3 through the first portion NDE3a, the second portion NDE3b, and the third portion NDE3c of the third node electrode.

The source electrode SE4 of the fourth transistor T4 may be electrically connected to the gate electrode GE2 of the second transistor T2, the source electrode SE3 of the third transistor T3, and the second capacitor electrode CPE2 of the first capacitor C1 through the first portion NDE4a of the fourth node electrode.

The fourth transistor T4 may further include the bias electrode BE4 disposed in the first gate layer GTL1. The bias electrode BE4 of the fourth transistor T4 may be integrally formed with the bias electrode of the eighth transistor T8, but is not limited thereto. The bias electrode BE4 of the fourth transistor T4 may be connected to the gate low voltage line VGLL.

The fifth transistor T5 may include the semiconductor region, the gate electrode, the source electrode, and the drain electrode. The semiconductor region, the source electrode, the drain electrode of the fifth transistor T5 may be disposed in the first active layer ACTL1, and the gate electrode of the fifth transistor T5 may be disposed in the first gate layer GTL1. The gate electrode of the fifth transistor T5 may overlap the semiconductor region. The gate electrode of the fifth transistor T5 may be electrically connected to the gate electrode of the sixth transistor T6, the drain electrode of the seventh transistor T7, and the drain electrode of the eighth transistor T8 through the second node electrode NDE2 disposed in the first source metal layer SDL1.

The source electrode of the fifth transistor T5 may be connected to the first portion of the gate high voltage line VGHL. The drain electrode of the fifth transistor T5 may be electrically connected to the drain electrode of the sixth transistor T6, and the first to third portions NDE4a, NDE4b, and NDE4c of the fourth node electrode through the carry-out line COL.

The sixth transistor T6 may include the semiconductor region, the gate electrode, the drain electrode, and the source electrode. The semiconductor region, the drain electrode, and the source electrode of the sixth transistor T6 may be disposed in the second active layer ACTL2, and the gate electrode of the sixth transistor T6 may be disposed in the third gate layer GTL3. The gate electrode of the sixth transistor T6 may overlap the semiconductor region. The gate electrode of the sixth transistor T6 may be electrically connected to the gate electrode of the fifth transistor T5, the drain electrode of the seventh transistor T7, and the drain electrode of the eighth transistor T8 through the second node electrode NDE2.

The drain electrode of the sixth transistor T6 may be electrically connected to the drain electrode of the fifth transistor T5, and the first to third portions NDE4a, NDE4b, and NDE4c of the fourth node electrode through the carry-out line COL. The source electrode of the sixth transistor T6 may be connected to the second portion of the gate low voltage line VGLL.

The sixth transistor T6 may further include the bias electrode disposed in the first gate layer GTL1. The bias electrode may be connected to the gate low voltage line VGLL.

The seventh transistor T7 may include the semiconductor region, the gate electrode, the source electrode, and the drain electrode. The semiconductor region, the source electrode, and the drain electrode of the seventh transistor T7 may be disposed in the first active layer ACTL1, and the gate electrode of the seventh transistor T7 may be disposed in the first gate layer GTL1. The gate electrode of the seventh transistor T7 may overlap the semiconductor region. The gate electrode of the seventh transistor T7 may be integrally formed with the first capacitor electrode CPE1 of the first capacitor C1, but is not limited thereto. The gate electrode of the seventh transistor T7 may be electrically connected to the drain electrode of the ninth transistor T9 through the first portion NDE1a of the first node electrode disposed in the first source metal layer SDL1. The gate electrode of the seventh transistor T7 may be electrically connected to the gate electrode of the eighth transistor T8 through the second portion NDE1b of the first node electrode disposed in the first source metal layer SDL1.

The source electrode of the seventh transistor T7 may be connected to the second portion of the gate high voltage line VGHL. The drain electrode of the seventh transistor T7 may be electrically connected to the gate electrode of the fifth transistor T5, the gate electrode of the sixth transistor T6, and the drain electrode of the eighth transistor T8 through the second node electrode NDE2.

The eighth transistor T8 may include the semiconductor region, the gate electrode, the drain electrode, and the source electrode. The semiconductor region, the drain electrode, and the source electrode of the eighth transistor T8 may be disposed in the second active layer ACTL2, and the gate electrode of the eighth transistor T8 may be disposed in the third gate layer GTL3. The gate electrode of the eighth transistor T8 may overlap the semiconductor region. The gate electrode of the eighth transistor T8 may be electrically connected to the gate electrode of the seventh transistor T7 through the second portion NDE1b of the first node electrode.

The drain electrode of the eighth transistor T8 may be electrically connected to the gate electrode of the fifth transistor T5, the gate electrode of the sixth transistor t6, and the drain electrode of the seventh transistor T7 through the second node electrode NDE2. The source electrode of the eighth transistor T8 may be connected to the third portion of the gate low voltage line VGLL.

The eighth transistor T8 may further include the bias electrode disposed in the first gate layer GTL1. The bias electrode of the eighth transistor T8 may be integrally formed with the bias electrode of the fourth transistor T4, but is not limited thereto. The bias electrode may be connected to the gate low voltage line VGLL.

The ninth transistor T9 may include the semiconductor region, the gate electrode, the source electrode, and the drain electrode. The semiconductor region, the source electrode, and the drain electrode of the ninth transistor T9 may be disposed in the first active layer ACTL1, and the gate electrode of the ninth transistor T9 may be disposed in the first gate layer GTL1. The gate electrode of the ninth transistor T9 may overlap the semiconductor region. The gate electrode of the ninth transistor T9 may be connected to the first clock line CKL1 disposed in the first source metal layer SDL1.

The source electrode of the ninth transistor T9 may be connected to a carry-in line CIL disposed in the first source metal layer SDL1. The source electrode of the ninth transistor T9 may receive the carry-in signal CRIN from the carry-in line CIL. The drain electrode of the ninth transistor T9 may be electrically connected to the first capacitor electrode CPE1 of the first capacitor C1 through the first portion NDE1a of the first node electrode.

As the stage STG includes the first to ninth transistors T1, T2, T3, T4, T5, T6, T7, T8, and T9 and the first capacitor C1, it is possible to reduce a size of the buffer of the stage STG, or the first transistor T1. Here, the buffer size may correspond to a width of the first transistor T1 or a width of the stage STG. The display device 10 may reduce a size of the scan driver 220 and power consumption, by reducing the buffer size.

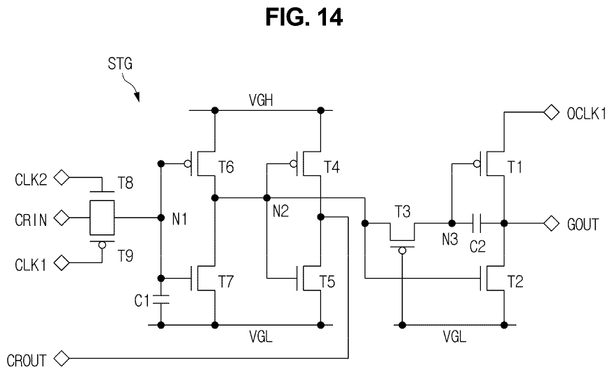

FIG. 14 is a circuit diagram illustrating a stage of a scan driver in a display device according to one or more other embodiments of the present disclosure.

Referring to FIG. 14, the stage STG may include first to ninth transistors T1, T2, T3, T4, T5, T6, T7, T8, and T9 and first and second capacitors C1 and C2.

The first transistor T1 may receive the first output clock signal OCLK1 based on a voltage of the third node N3, and may output the gate output signal GOUT. Here, the third node N3 may be connected to the gate electrode of the first transistor T1, the drain electrode of the third transistor T3, and the first capacitor electrode of the second capacitor C2. The drain electrode of the first transistor T1 may be connected to the third node N3, the source electrode of the first transistor T1 may receive the first output clock signal OCLK1, and the drain electrode of the first transistor T1 may output the gate output signal GOUT.

The second transistor T2 may discharge the gate output signal GOUT to the gate low voltage VGL based on the voltage of the second node N2. Here, the second node N2 may be connected to the gate electrode of the second transistor T2, the source electrode of the third transistor T3, the gate electrode of the fourth transistor T4, the gate electrode of the fifth transistor T5, the drain electrode of the sixth transistor T6, and the drain electrode of the seventh transistor T7. The gate electrode of the second transistor T2 may be connected to the second node N2, the drain electrode of the second transistor T2 may receive the gate output signal GOUT, and the source electrode of the second transistor T2 may receive the gate low voltage VGL.

The third transistor T3 may supply the voltage of the second node N2 to the third node N3 based on the gate low voltage VGL. The gate electrode of the third transistor T3 may receive the gate low voltage VGL, the source electrode of the third transistor T3 may be connected to the second node N2, and the drain electrode of the third transistor T3 may be connected to the third node N3.

The fourth transistor T4 may receive the gate high voltage VGH based on the voltage of the second node N2, and may output the carry-out signal CROUT. The gate electrode of the fourth transistor T4 may be connected to the second node N2, the source electrode of the fourth transistor T4 may receive the gate high voltage VGH, and the drain electrode of the fourth transistor T4 may output the carry-out signal CROUT.

The fifth transistor T5 may discharge the carry-out signal CROUT to the gate low voltage VGL based on the voltage of the second node N2. The gate electrode of the fifth transistor T5 may be connected to the second node N2, the drain electrode of the fifth transistor T5 may output the carry-out signal CROUT, and the source electrode of the fifth transistor T5 may receive the gate high voltage VGH.

The sixth transistor T6 may supply the gate high voltage VGH to the second node N2 based on the voltage of the first node N1. Here, the first node N1 may be connected to the gate electrode of the sixth transistor T6, the gate electrode of the seventh transistor T7, the source electrode of the eighth transistor T8, the drain electrode of the ninth transistor T9, and the first capacitor electrode of the first capacitor C1. The gate electrode of the sixth transistor T6 may be connected to the first node N1, the source electrode of the sixth transistor T6 may receive the gate high voltage VGH, and the drain electrode of the sixth transistor T6 may be connected to the second node N2.

The seventh transistor T7 may discharge the voltage of the second node N2 to the gate low voltage VGL based on the voltage of the first node N1. The gate electrode of the seventh transistor T7 may be connected to the first node N1, the drain electrode of the seventh transistor T7 may be connected to the second node N2, and the source electrode of the seventh transistor T7 may receive the gate low voltage VGL.

The eighth transistor T8 may supply the carry-in signal CRIN to the first node N1 based on the second clock signal CLK2. The gate electrode of the eighth transistor T8 may receive the second clock signal CLK2, the drain electrode of the eighth transistor T8 may receive the carry-in signal CRIN, and the source electrode of the eighth transistor T8 may be connected to the first node N1.

The ninth transistor T9 may supply the carry-in signal CRIN to the first node N1 based on the first clock signal CLK1. The gate electrode of the ninth transistor T9 may receive the first clock signal CLK1, the source electrode of the ninth transistor T9 may receive the carry-in signal CRIN, and the drain electrode of the ninth transistor T9 may be connected to the first node N1.

The first capacitor C1 may be connected between the first node N1 and the gate low voltage VGL, and may maintain a potential difference between the first node N1 and the gate low voltage VGL.

The second capacitor C2 may be connected between the third node N3 and the gate output signal GOUT, and may maintain a potential difference between the third node N3 and the gate output signal GOUT.

The first transistor T1, the third transistor T3, the fourth transistor T4, the sixth transistor T6, and the ninth transistor T9 may include a silicon-based semiconductor region. For example, the first transistor T1, the third transistor T3, the fourth transistor T4, the sixth transistor T6, and the ninth transistor T9 may include a semiconductor region formed of the Low Temperature Polycrystalline Silicon (LTPS). The semiconductor region formed of the Low Temperature Polycrystalline Silicon (LTPS) has a high electron mobility, and an excellent turn-on characteristic.

The first transistor T1, the third transistor T3, the fourth transistor T4, the sixth transistor T6, and the ninth transistor T9 may be p-type transistors. For example, the first transistor T1, the third transistor T3, the fourth transistor T4, the sixth transistor T6, and the ninth transistor T9 may output a current introduced into the first electrode to the second electrode based on the gate low voltage VGL applied to the gate electrode. A first electrode of each of the first transistor T1, the third transistor T3, the fourth transistor T4, the sixth transistor T6, and the ninth transistor T9 may be a source electrode, and a second electrode of each thereof may be a drain electrode.

The second transistor T2, the fifth transistor T5, the seventh transistor T7, and the eighth transistor T8 may include an oxide-based semiconductor region. For example, the second transistor T2, the fifth transistor T5, the seventh transistor T7, and the eighth transistor T8 may have a coplanar structure in which a gate electrode is disposed on an upper portion of the oxide-based semiconductor region. The transistor having the coplanar structure may have an excellent leakage current characteristic and allow a low frequency driving, thereby being able to reduce the power consumption.

The second transistor T2, the fifth transistor T5, the seventh transistor T7, and the eighth transistor T8 may be n-type transistors. For example, the second transistor T2, the fifth transistor T5, the seventh transistor T7, and the eighth transistor T8 may output a current introduced into the first electrode to the second electrode based on the gate high voltage VGH which is applied to the gate electrode. Here, a first electrode of each of the second transistor T2, the fifth transistor T5, the seventh transistor T7, and the eighth transistor T8 may be a drain electrode, and a second electrode of each thereof may be a source electrode.

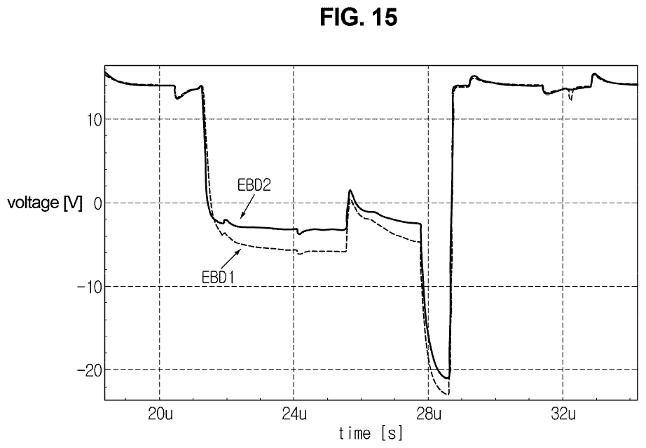

FIG. 15 is a waveform diagram comparing a voltage of the third node of the stage in FIG. 4 and the stage in FIG. 14.

Referring to FIG. 15, the stage in FIG. 4 may correspond to the first embodiment EBD1, and the stage in FIG. 14 may correspond to the second embodiment EBD2.

As shown in FIG. 5, the voltage VN3 of the third node N3 may have a first low level at the second to fourth intervals t2, t3, and t4, and may have a second low level which is lower than the first low level at the fifth interval t5. In the stage STG of the first embodiment EBD1, the voltage VN3 of the third node N3 may fall closer to the ideal first low level at the second to fourth intervals t2, t3, and t4, and may fall closer to the ideal second low level at the fifth interval t5. In the stage STG of the second embodiment EBD2, the voltage VN3 of the third node N3 may fall relatively less at the second to fourth intervals t2, t3, and t4 than that of the stage STG of the first embodiment EBD1.

The stage STG of the first embodiment EBD1 may include a third transistor T3 in a p-type connected between the fourth node N4 and the third node N3, and a fourth transistor T4 diode-connected between the third node N3 and the fourth node N4. Here, a magnitude of the threshold voltage of the fourth transistor T4 may be smaller than a magnitude of the threshold voltage of the third transistor T3, and may make the voltage VN3 of the third node N3 fall relatively more. The stage STG of the first embodiment EBD1 may sufficiently secure the gate-source voltage Vgs between the gate electrode of the first transistor T1 and the first output clock signal OCLK1, without adding an additional line. The stage STG of the first embodiment EBD1 may reduce a delay time of the gate output signal GOUT by reducing a load of the first output clock signal OCLK1. Therefore, the stage STG of the first embodiment EBD1 may secure reliability of the gate output signal GOUT by reducing the rise time, the fall time, and the propagation delay of the gate output signal GOUT.

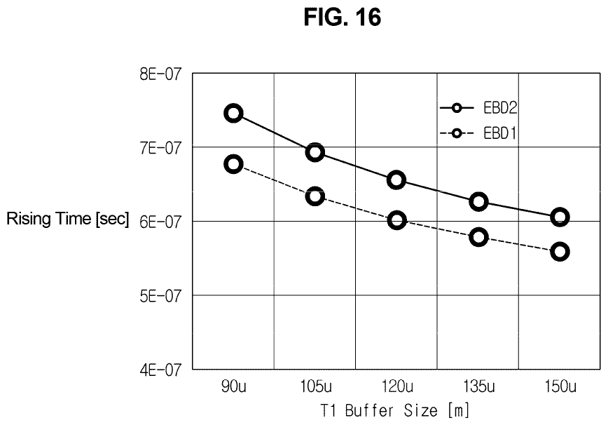

FIG. 16 is a graph illustrating the rise time of the gate output signal according to the buffer size of the first transistor in the stage of FIG. 4 and the stage of FIG. 14.

Referring to FIG. 16, as the buffer size of the stage STG of the first transistor T1 increases, the rise time of the gate output signal GOUT may decrease. As the buffer size of the first transistor T1 increases from 90[μm] to 150[μm], the rise time of the gate output signal GOUT may decrease. When the buffer size of the first transistor T1 is the same, the rise time of the gate output signal GOUT of the first embodiment EDB1 may be shorter than the rise time of the gate output signal GOUT of the second embodiment EDB2. Therefore, the stage STG of the first embodiment EDB1 may decrease the rise time of the gate output signal GOUT while maintaining the buffer size of the first transistor T1 to be in a regular level.

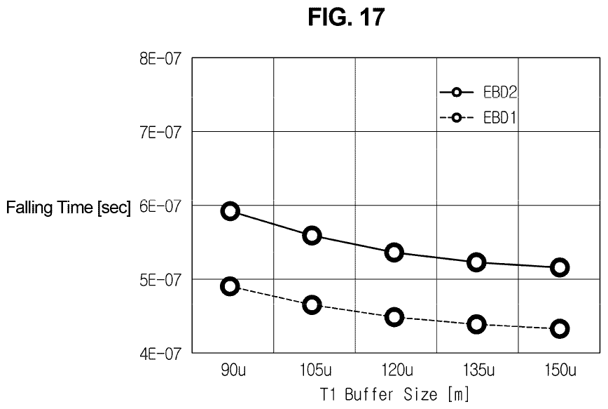

FIG. 17 is a graph illustrating the fall time of the gate output signal according to the buffer size of the first transistor in the stage of FIG. 4 and the stage of FIG. 14.

Referring to FIG. 17, as the buffer size of the stage STG of the first transistor T1 increases, the fall time of the gate output signal GOUT may decrease. As the buffer size of the first transistor T1 increases from 90[μm] to 150[μm], the fall time of the gate output signal GOUT may decrease. When the buffer size of the first transistor T1 is the same, the fall time of the gate output signal GOUT of the first embodiment EDB1 may be shorter than the fall time of the gate output signal GOUT of the second embodiment EDB2. Therefore, the stage STG of the first embodiment EDB1 may decrease the fall time of the gate output signal GOUT while maintaining the buffer size of the first transistor T1 to be in a regular level.

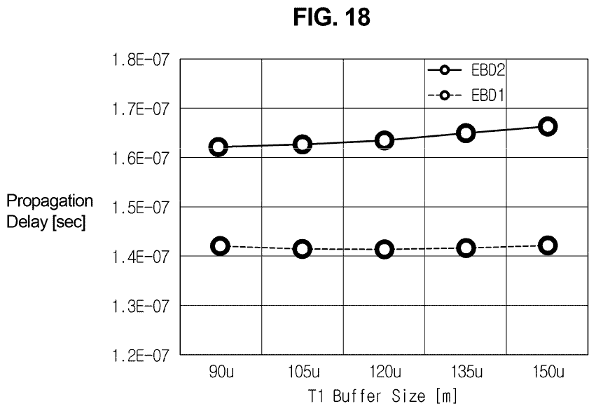

FIG. 18 is a graph illustrating the propagation delay of the gate output signal according to the buffer size of the first transistor in the stage of FIG. 4 and the stage of FIG. 14.

Referring to FIG. 18, the stage STG of the first embodiment EDB1 may have the propagation delay which is generally similar without being greatly influenced by the buffer size of the first transistor T1. Here, the propagation delay may correspond to a delay time between a time point when the first output clock signal OCLK1 rises and a time point when the gate output signal GOUT rises. In the stage STG of the second embodiment EDB2, as the buffer size of the first transistor T1 increases, the propagation delay of the gate output signal GOUT may increase. When the buffer size of the first transistor T1 is the same, the propagation delay of the gate output signal GOUT of the first embodiment EDB1 may be shorter than the propagation delay of the gate output signal GOUT of the second embodiment EDB2. Therefore, the stage STG of the first embodiment EDB1 may decrease the propagation delay of the gate output signal GOUT while maintaining the buffer size of the first transistor T1 to be in a regular level.

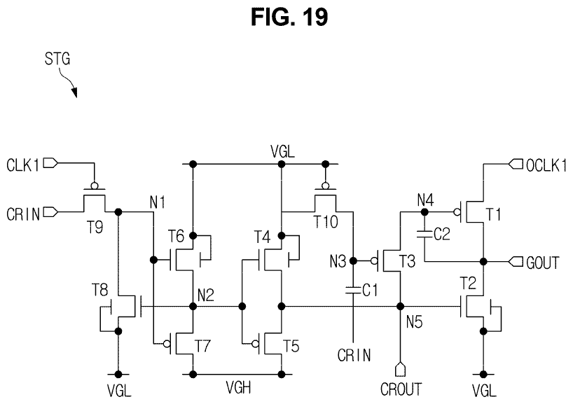

FIG. 19 is a circuit diagram illustrating a stage of a scan driver in a display device according to one or more other embodiments of the present disclosure.

Referring to FIG. 19, the stage STG may include first to tenth transistors T1, T2, T3, T4, T5, T6, T7, T8, T9, and T10, and first and second capacitors C1 and C2.

The first transistor T1 may receive the first output clock signal OCLK1 based on the voltage of the fourth node N4, and may output the gate output signal GOUT. Here, the fourth node N4 may be connected to the gate electrode of the first transistor T1, the drain electrode of the third transistor T3, and the first capacitor electrode of the second capacitor C2. The drain electrode of the first transistor T1 may be connected to the fourth node N4, the source electrode of the first transistor T1 may receive the first output clock signal OCLK1, and the drain electrode of the first transistor T1 may output the gate output signal GOUT.

The second transistor T2 may discharge the gate output signal GOUT to the gate low voltage VGL based on the voltage of the fifth node N5. Here, the fifth node N5 may output the carry-out signal CROUT, and may be connected to the gate electrode of the second transistor T2, the source electrode of the third transistor T3, the drain electrode of the fourth transistor T4, and the drain electrode of the fifth transistor T5. The gate electrode of the second transistor T2 may be connected to the fifth node N5, the drain electrode of the second transistor T2 may receive the gate output signal GOUT, and the source electrode of the second transistor T2 may receive the gate low voltage VGL. The second transistor T2 may further include a bias electrode overlapping the gate electrode, or a bottom gate electrode. The bias electrode of the second transistor T2 may receive the gate low voltage VGL.

The third transistor T3 may supply a voltage of the fifth node N5 to the fourth node N4 based on the voltage of the third node N3. Here, the third node N3 may be connected to the gate electrode of the third transistor T3, the source electrode of the tenth transistor T10, the first capacitor electrode of the first capacitor C1. The gate electrode of the third transistor T3 may be connected to the third node N3, the source electrode of the third transistor T3 may be connected to the fifth node N5, and the drain electrode of the third transistor T3 may be connected to the fourth node N4.

The fourth transistor T4 may discharge the voltage of the fifth node N5 to the gate low voltage VGL based on the voltage of the second node N2. Here, the second node N2 may be connected to the gate electrode of the fourth transistor T4, the gate electrode of the fifth transistor T5, the drain electrode of the sixth transistor T6, the drain electrode of the seventh transistor T7, and the gate electrode of the eighth transistor T8. The gate electrode of the fourth transistor T4 may be connected to the second node N2, the drain electrode of the fourth transistor T4 may be connected to the fifth node N5, and the source electrode of the fourth transistor T4 may receive the gate low voltage VGL. The fourth transistor T4 may further include a bias electrode overlapping the gate electrode, or a bottom gate electrode. A bias electrode of the fourth transistor T4 may receive the gate low voltage VGL.

The fifth transistor T5 may supply the gate high voltage VGH to the fifth node N5 based on the voltage of the second node N2. The gate electrode of the fifth transistor T5 may be connected to the second node N2, the source electrode of the fifth transistor T5 may receive the gate high voltage VGH, and the drain electrode of the fifth transistor T5 may be connected to the fifth node N5.

The sixth transistor T6 may discharge the voltage of the second node N2 to the gate low voltage VGL based on the voltage of the first node N1. Here, the first node N1 may be connected to the gate electrode of the sixth transistor T6, the gate electrode of the seventh transistor T7, the drain electrode of the eighth transistor T8, and the drain electrode of the ninth transistor T9. The gate electrode of the sixth transistor T6 may be connected to the first node N1, the drain electrode of the sixth transistor T6 may be connected to the second node N2, and the source electrode of the sixth transistor T6 may receive the gate low voltage VGL. The sixth transistor T6 may further include a bias electrode overlapping the gate electrode, or a bottom gate electrode. A bias electrode of the sixth transistor T6 may receive the gate low voltage VGL.

The seventh transistor T7 may supply the gate high voltage VGH to the second node N2 based on the voltage of the first node N1. The gate electrode of the seventh transistor T7 may be connected to the first node N1, the source electrode of the seventh transistor T7 may receive the gate high voltage VGH, and the drain electrode of the seventh transistor T7 may be connected to the second node N2.

The eighth transistor T8 may discharge the voltage of the first node N1 to the gate low voltage VGL based on the voltage of the second node N2. The gate electrode of the eighth transistor T8 may be connected to the second node N2, the drain electrode of the eighth transistor T8 may be connected to the first node N1, and the source electrode of the eighth transistor T8 may receive the gate low voltage VGL. The eighth transistor T8 may further include a bias electrode overlapping the gate electrode, or a bottom gate electrode. A bias electrode of the eighth transistor T8 may receive the gate low voltage VGL.

The ninth transistor T9 may supply the carry-in signal CRIN to the first node N1 based on the first clock signal CLK1. The carry-in signal CRIN received by the stage STG in FIG. 19 may be the carry-out signal CROUT of a previous stage. The ninth transistor T9 of a next stage of the stage STG in FIG. 19 may supply the carry-in signal CRIN to the first node N1 based on the second clock signal CLK2. The gate electrode of the ninth transistor T9 may receive the first clock signal CLK1, the source electrode of the ninth transistor T9 may receive the carry-in signal CRIN, and the drain electrode of the ninth transistor T9 may be connected to the first node N1.

The tenth transistor T10 may discharge the voltage of the third node N3 to the gate low voltage VGL based on the gate low voltage VGL. The gate electrode and the drain electrode of the tenth transistor T10 may receive the gate low voltage VGL, and the source electrode of the tenth transistor T10 may be connected to the third node N3.

The first capacitor C1 may be connected between the third node N3 and the carry-in signal CRIN, and may maintain a potential difference between the third node N3 and the carry-in signal CRIN.

The second capacitor C2 may be connected between the fourth node N4 and the gate output signal GOUT, and may maintain a potential difference between the fourth node N4 and the gate output signal GOUT.

The first transistor T1, the third transistor T3, the fifth transistor T5, the seventh transistor T7, and the ninth transistor T9 may include a silicon-based semiconductor region. For example, the first transistor T1, the third transistor T3, the fifth transistor T5, the seventh transistor T7, and the ninth transistor T9 may include a semiconductor region formed of the Low Temperature Polycrystalline Silicon (LTPS). The semiconductor region formed of the Low Temperature Polycrystalline Silicon (LTPS) has a high electron mobility, and an excellent turn-on characteristic. Therefore, as the display device 10 includes the first transistor T1, the third transistor T3, the fifth transistor T5, the seventh transistor T7, and the ninth transistor T9 having an excellent turn-on characteristic, the display device 10 may drive the scan driver 220 stably and efficiently.

The first transistor T1, the third transistor T3, the fifth transistor T5, the seventh transistor T7, and the ninth transistor T9 may be p-type transistors. For example, the first transistor T1, the third transistor T3, the fifth transistor T5, the seventh transistor T7, and the ninth transistor T9 may output a current introduced into the first electrode to the second electrode based on the gate low voltage VGL which is applied to the gate electrode. A first electrode of each of the first transistor T1, the third transistor T3, the fifth transistor T5, the seventh transistor T7, and the ninth transistor T9 may be a source electrode, and a second electrode of each thereof may be a drain electrode.

The second transistor T2, the fourth transistor T4, the sixth transistor T6, and the eighth transistor T8 may include an oxide-based semiconductor region. For example, the second transistor T2, the fourth transistor T4, the sixth transistor T6, and the eighth transistor T8 may have a coplanar structure in which a gate electrode is disposed on an upper portion of the oxide-based semiconductor region. The transistor having the coplanar structure may have an excellent leakage current characteristic and allow a low frequency driving, thereby being able to reduce the power consumption. Therefore, as the display device 10 includes the second transistor T2, the fourth transistor T4, the sixth transistor T6, and the eighth transistor T8 having the excellent leakage current characteristic, the display device 10 may prevent or reduce the leakage current from flowing in the stage STG, and may maintain a voltage inside the stage STG stably, thereby improving reliability of the scan signal.

The second transistor T2, the fourth transistor T4, the sixth transistor T6, and the eighth transistor T8 may be n-type transistors. For example, the second transistor T2, the fourth transistor T4, the sixth transistor T6, and the eighth transistor T8 may output a current introduced into the first electrode to the second electrode based on the gate high voltage VGH which is applied to the gate electrode. Here, a first electrode of each of the second transistor T2, the fourth transistor T4, the sixth transistor T6, and the eighth transistor T8 may be a drain electrode, and a second electrode of each thereof may be a source electrode.

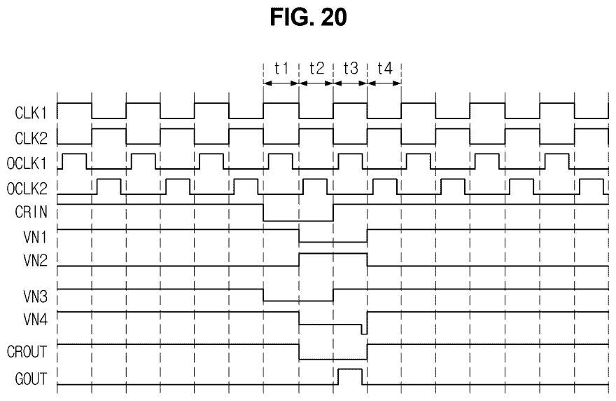

FIG. 20 is a waveform diagram illustrating an input/output signal of a stage in a display device according to one or more other embodiments of the present disclosure.

Referring to FIG. 20, the clock line CKL may supply the first and second clock signals CLK1 and CLK2 to the stages STG. The first and second clock signals CLK1 and CLK2 may alternately have a high level and a low level based on a predetermined frequency. The first and second clock signals CLK1 and CLK2 may have a phase difference of 180 degrees. The first clock signal CLK1 may have a high level at a first interval t1 and a third interval t3, and may have a low level at a second interval t2 and a fourth interval t4. The second clock signal CLK2 may have a high level at the second interval t2 and the fourth interval t4, and may have a low level at the first interval t1 and the third interval t3.

The output clock line OCKL may supply the first and second output clock signals OCLK1 and OCLK2 to the stages STG. The first and second output clock signals OCLK1 and OCLK2 may sequentially have a high level. The first output clock signal OCLK1 may have a high level at the first interval t1 and the third interval t3. The second output clock signal OCLK2 may have a high level at the second interval t2 and the fourth interval t4.

The carry-in signal CRIN received by the stage STG may be the carry-out signal CROUT of a previous stage. The carry-out signal CROUT output from the stage STG may be the carry-in signal CRIN of the next stage. The carry-in signal CRIN may have a low level at the first and second intervals t1 and t2. The carry-out signal CROUT output from the stage STG may be a delay signal of the carry-in signal CRIN received by the stage STG. Therefore, the carry-out signal CROUT may have a low level at the second and third intervals t2 and t3.

As shown in FIG. 19, the gate electrode of the ninth transistor T9 may receive the first clock signal CLK1 in a low level at the second interval t2. The ninth transistor T9 may supply the carry-in signal CRIN to the first node N1 based on the first clock signal CLK1 in a low level. The eighth transistor T8 may discharge a voltage of the first node N1 to the gate low voltage VGL based on the voltage of the second node N2. The voltage VN2 of the second node N2 may have a low level at the second and third intervals t2 and t3. Therefore, the voltage VN1 of the first node N1 may have a low level at the second and third intervals t2 and t3.

The gate electrode of the seventh transistor T7 may receive the voltage VN1 of the first node N1 in a low level at the second and third intervals t2 and t3. The seventh transistor T7 may supply the gate high voltage VGH to the second node N2 based on the voltage VN1 of the first node N1 in a low level.

The gate electrode of the sixth transistor T6 may receive the voltage VN1 of the first node N1 in a high level at the fourth interval t4. The sixth transistor T6 may discharge the voltage VN2 of the second node N2 to the gate low voltage VGL based on the voltage VN1 of the first node N1 in a high level.

The gate electrode of the fourth transistor T4 may receive the voltage VN2 of the second node N2 in a high level at the second and third intervals t2 and t3. The fourth transistor T4 may discharge the voltage VN5 of the fifth node N5 in a high level to the gate low voltage VGL based on the voltage VN2 of the second node N2 in a high level.

The gate electrode of the fifth transistor T5 may receive the voltage VN2 of the second node N2 in a low level at the fourth interval t4. The fifth transistor T5 may supply the gate high voltage VGH to the fifth node N5 based on the voltage VN2 of the second node N2 in a low level. Therefore, the carry-out signal CROUT may have a low level at the second and third intervals t2 and t3, and may have a high level from the fourth interval t4.

The third transistor T3 may maintain a turn-on state at the first to fourth intervals t1, t2, t3 and t4 based on the voltage VN3 of the third node N3. The voltage VN3 of the third node N3 may be discharged to the gate low voltage VGL by the tenth transistor T10 at the first to fourth intervals t1, t2, t3 and t4. The voltage VN3 of the third node N3 may have the first low level at the first and second intervals t1 and t2, and may have a second low level at the third and fourth intervals t3 and t4. As the voltage VN3 of the third node N3 is bootstrapped by a falling edge of the carry-in signal CRIN, the voltage VN3 of the third node N3 may have the second low level, which is lower than the first low level, at the first and second intervals t1 and t2. Here, the second low level of the voltage VN3 of the third node N3 may be lower than the gate low voltage VGL. The third transistor T3 may be turned on based on the second low level at the second interval t2, and may supply the carry-out signal CROUT in a low level to the fourth node N4. Therefore, the carry-out signal CROUT may be delivered to the fourth node N4 as it is, without being influenced by a magnitude of the threshold voltage of the third transistor T3. At the second interval t2, the carry-out signal CROUT and the voltage VN4 of the fourth node N4 may be substantially the same. At the second interval t2, a difference or a gap between the carry-out signal CROUT and the voltage VN4 of the fourth node N4 may be close to 0.

The first transistor T1 may receive the first output clock signal OCLK1 based on the voltage VN4 of the fourth node N4, and may output the gate output signal GOUT. The first output clock signal OCLK1 may have a high level at the first interval t1 and the third intervals t1 and t3, and may have a low level at the second interval t2 and the fourth intervals t2 and t4. The second transistor T2 may receive the voltage of the fifth node N5 in a high level at the fourth interval t4. The second transistor T2 may discharge the gate output signal GOUT to the gate low voltage VGL based on the voltage of the fifth node N5 in a high level. Therefore, the gate output signal GOUT may have a high level at the third interval t3, and may have a low level from the fourth interval t4. The second transistor T2 may reduce a fall time of the gate output signal GOUT.

As the voltage VN4 of the fourth node N4 is bootstrapped by a falling edge of the gate output signal GOUT, the voltage VN4 of the fourth node N4 may have a second low level, which is lower than the first low level, at the latter half of the third interval t3. Here, the second low level of the voltage VN4 of the fourth node N4 may be lower than the gate low voltage VGL. The third transistor T3 may prevent or reduce the voltage VN4 of the fourth node N4 from being delivered to the fifth node N5. Therefore, the carry-out signal CROUT may maintain a low level at the third interval t3, without being influenced by the voltage VN4 of the fourth node N4.

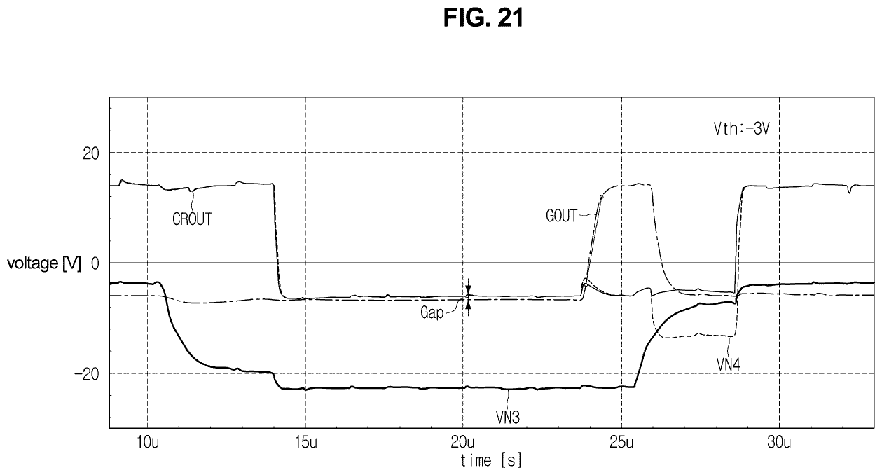

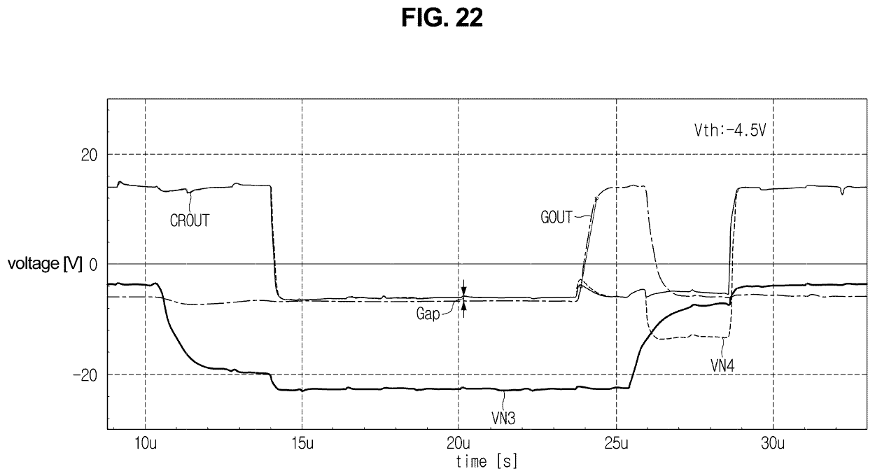

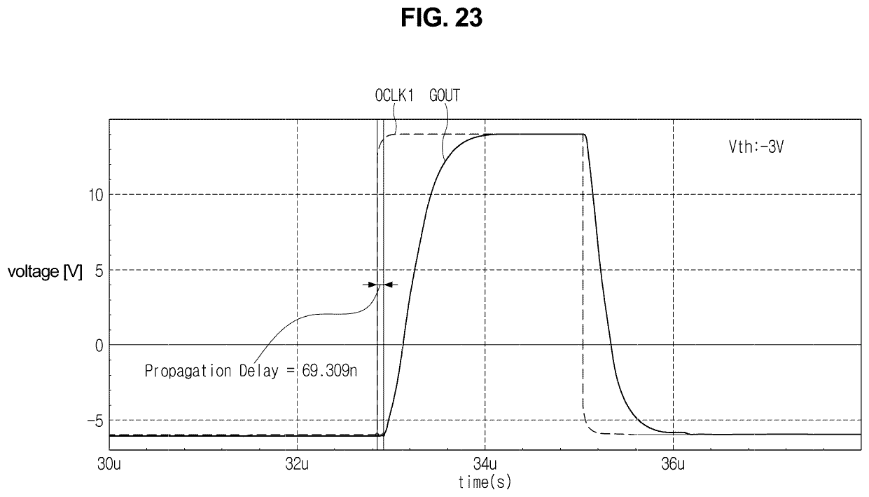

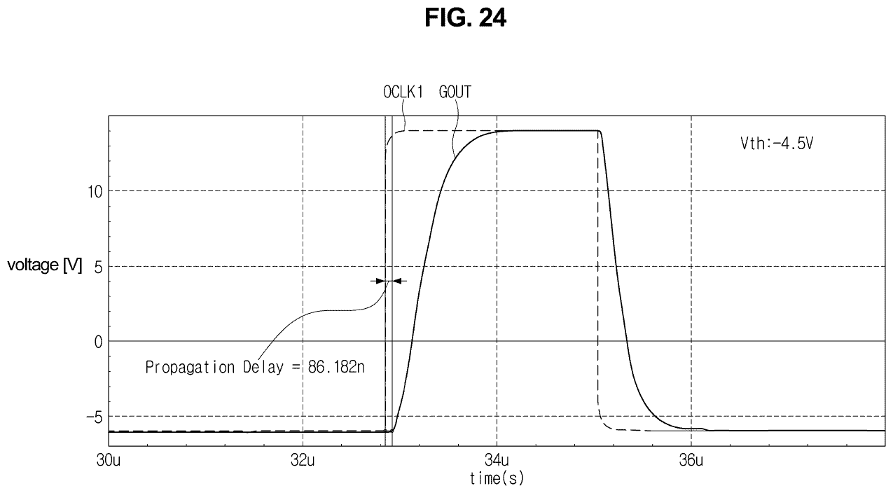

FIG. 21 is a waveform diagram illustrating a gap between the carry-out signal and the gate output signal according to a first threshold voltage of the third transistor in a display device according to one or more other embodiments of the present disclosure, FIG. 22 is a waveform diagram illustrating a gap between the carry-out signal and the gate output signal according to a second threshold voltage of the third transistor in a display device according to one or more other embodiments of the present disclosure, FIG. 23 is a graph illustrating a propagation delay of the gate output signal according to a first threshold voltage of the third transistor in a display device according to one or more other embodiments of the present disclosure, and FIG. 24 is a graph illustrating a propagation delay of the gate output signal according to a second threshold voltage of the third transistor in a display device according to one or more other embodiments of the present disclosure. Here, the first threshold voltage corresponds to −3[V], and the second threshold voltage corresponds to −4.5[V].

Referring to FIG. 20, and 21 to 24, the third transistor T3 may maintain a turn-on state at the first to fourth intervals t1, t2, t3, and t4 based on the voltage VN3 of the third node N3. The voltage VN3 of the third node N3 may be discharged to the gate low voltage VGL at the first to fourth intervals t1, t2, t3, and t4 by the tenth transistor T10. The voltage VN3 of the third node N3 may have a first low level at the first and second intervals t1 and t2, and may have a second low level at the third and fourth intervals t3 and t4. As the voltage VN3 of the third node N3 is bootstrapped by a falling edge of the carry-in signal CRIN, the voltage VN3 of the third node N3 may have a second low level, which is lower than the first low level, at the first and second intervals t1 and t2. Here, the second low level of the voltage VN3 of the third node N3 may be lower than the gate low voltage VGL. The third transistor T3 may be turned on based on the second low level at the second interval t2, and may supply the carry-out signal CROUT in a low level to the fourth node N4. Therefore, the carry-out signal CROUT may be delivered to the fourth node N4 as it is, without being influenced by a magnitude of the threshold voltage of the third transistor T3. At the second interval t2, the carry-out signal CROUT and the voltage VN4 of the fourth node N4 may be substantially the same. At the second interval t2, a difference or a gap between the carry-out signal CROUT and the voltage VN4 of the fourth node N4 may be close to 0. As the stage STG delivers the carry-out signal CROUT to the fourth node N4 as it is, the stage STG may secure reliability of the gate output signal GOUT by reducing the rise time, the fall time, and the propagation delay of the gate output signal GOUT.

The first transistor T1 may receive the first output clock signal OCLK1 based on the voltage VN4 of the fourth node N4 and may output the gate output signal GOUT. The first output clock signal OCLK1 may have a high level at the first and third intervals t1 and t3, and may have a low level at the second and fourth intervals t2 and t4. The second transistor T2 may receive the voltage of the fifth node N5 in a high level at the fourth interval t4. The second transistor T2 may discharge the gate output signal GOUT to the gate low voltage VGL based on the voltage of the fifth node N5 in a high level. Therefore, the gate output signal GOUT may have a high level at the third interval t3, and may have a low level from the fourth interval t4. The second transistor T2 may reduce the fall time of the gate output signal GOUT.

As the voltage VN4 of the fourth node N4 is bootstrapped by the falling edge of the gate output signal GOUT, the voltage VN4 of the fourth node N4 may have a second low level, which is lower than the first low level, at the latter half of the third interval t3. Here, the second low level of the voltage VN4 of the fourth node N4 may be lower than the gate low voltage VGL. The third transistor T3 may prevent or reduce the voltage VN4 of the fourth node N4 from being delivered to the fifth node N5. Therefore, the carry-out signal CROUT may maintain a low level at the third interval t3, without being influenced by the voltage VN4 of the fourth node N4.

The display device 10 according to various embodiments of the present disclosure may be described as below.

In one or more embodiments, a scan driver includes: a stage configured to receive a clock signal, an output clock signal, and a carry-in signal and output a gate output signal and a carry-out signal, and the stage may include: a first transistor configured to receive the output clock signal based on a voltage of a first node and output the gate output signal; a second transistor configured to discharge the gate output signal to a gate low voltage based on a voltage of a second node outputting the carry-out signal; a third transistor configured to supply the voltage of the second node to the first node based on the gate low voltage; and a fourth transistor configured to supply the voltage of the first node to the second node based on the voltage of the first node.

In a scan driver according to one or more embodiments of the present disclosure, the stage may further include: a fifth transistor configured to supply a gate high voltage to the second node based on a voltage of a third node; and a sixth transistor configured to discharge the voltage of the second node to the gate low voltage based on the voltage of the third node.

In a scan driver according to one or more embodiments of the present disclosure, the stage may further include: a seventh transistor configured to supply the gate high voltage to the third node based on a voltage of a fourth node; and an eighth transistor configured to discharge the voltage of the third node to the gate low voltage based on the voltage of the fourth node.

In a scan driver according to one or more embodiments of the present disclosure, the stage may further include: a ninth transistor configured to supply the carry-in signal to the fourth node based on the clock signal; and a first capacitor connected between the fourth node and the carry-out signal.

In a scan driver according to one or more embodiments of the present disclosure, the stage may further include: a first active layer disposed on a substrate and including a first material; a first gate layer disposed on the first active layer; a second gate layer disposed on the first gate layer; a second active layer disposed on the second gate layer and including a second material different from the first material; and a third gate layer disposed on the second active layer, and the first transistor and the third transistor may include a semiconductor region disposed on the first active layer, and the second transistor and the fourth transistor may include a semiconductor region disposed on the second active layer.

In a scan driver according to one or more embodiments of the present disclosure, the first capacitor may include: a first capacitor electrode disposed on the first gate layer and connected to a drain electrode of the ninth transistor; and a second capacitor electrode disposed on the second gate layer and configured to receive the carry-out signal.

In a scan driver according to one or more embodiments of the present disclosure, each of the second transistor and the fourth transistor may include a bias electrode disposed on the first gate layer and configured to receive the gate low voltage.

In a scan driver according to one or more embodiments of the present disclosure, each of the sixth transistor and the eighth transistor may include a bias electrode disposed on the first gate layer and configured to receive the gate low voltage.

In one or more other embodiments, a display device includes: a display panel comprising data lines configured to supply a data voltage, scan lines intersecting the data lines and configured to supply a scan signal, and pixels connected to the data lines and the scan lines; a display driver configured to supply the data voltage to the data lines; and a scan driver configured to sequentially supply the scan signals to the scan lines, and the scan driver may include: a stage configured to receive a clock signal, an output clock signal, and a carry-in signal and output a gate output signal and a carry-out signal corresponding to the scan signal, and the stage may include: a first transistor configured to receive the output clock signal based on a voltage of a first node and output the gate output signal; a second transistor configured to discharge the gate output signal to a gate low voltage based on a voltage of a second node outputting the carry-out signal; a third transistor configured to supply the voltage of the second node to the first node based on the gate low voltage; and a fourth transistor configured to supply the voltage of the first node to the second node based on the voltage of the first node.

In a display device according to one or more embodiments of the present disclosure, the stage may further include: a fifth transistor configured to supply a gate high voltage to the second node based on a voltage of a third node; and a sixth transistor configured to discharge the voltage of the second node to the gate low voltage based on the voltage of the third node.

In a display device according to one or more embodiments of the present disclosure, the stage may further include: a seventh transistor configured to supply the gate high voltage to the third node based on a voltage of a fourth node; and an eighth transistor configured to discharge the voltage of the third node to the gate low voltage based on the voltage of the fourth node.

In a display device according to one or more embodiments of the present disclosure, the stage may further include: a ninth transistor configured to supply the carry-in signal to the fourth node based on the clock signal; and a first capacitor connected between the fourth node and the carry-out signal.

In one or more other embodiments, a scan driver includes: a stage configured to receive a clock signal, an output clock signal, and a carry-in signal and output a gate output signal and a carry-out signal, and the stage may include: a first transistor configured to receive the output clock signal based on a voltage of a first node and output the gate output signal; a second transistor configured to discharge the gate output signal to a gate low voltage based on a voltage of a second node outputting the carry-out signal; a third transistor configured to supply the voltage of the second node to the first node based on a voltage of a third node; a fourth transistor configured to discharge the voltage of the third node to the gate low voltage based on the gate low voltage; and a first capacitor connected between the carry-in signal and the third node.

In a scan driver according to one or more embodiments of the present disclosure, the stage may further include: a fifth transistor configured to discharge the voltage of the second node to the gate low voltage based on a voltage of a fourth node; and a sixth transistor configured to supply a gate high voltage to the second node based on the voltage of the fourth node.

In a scan driver according to one or more embodiments of the present disclosure, the stage may further include: a seventh transistor configured to discharge the voltage of the fourth node to the gate low voltage based on a voltage of a fifth node; and an eighth transistor configured to supply the gate high voltage to the fourth node based on the voltage of the fifth node.

In a scan driver according to one or more embodiments of the present disclosure, the stage may further include: a ninth transistor configured to discharge the voltage of the fifth node to the gate low voltage based on the voltage of the fourth node; a tenth transistor configured to supply the carry-in signal to the fifth node based on the clock signal; and a second capacitor connected between the first node and the gate output signal.

In one or more other embodiments, a display device includes: a display panel comprising data lines configured to supply a data voltage, scan lines intersecting the data lines and configured to supply a scan signal, and pixels connected to the data lines and the scan lines; a display driver configured to supply the data voltage to the data lines; and a scan driver configured to sequentially supply the scan signals to the scan lines, and the scan driver may include: a stage configured to receive a clock signal, an output clock signal, and a carry-in signal and output a gate output signal and a carry-out signal corresponding to the scan signal, and the stage may include: a first transistor configured to receive the output clock signal based on a voltage of a first node and output the gate output signal; a second transistor configured to discharge the gate output signal to a gate low voltage based on a voltage of a second node outputting the carry-out signal; a third transistor configured to supply the voltage of the second node to the first node based on a voltage of a third node; a fourth transistor configured to discharge the voltage of the third node to the gate low voltage based on the gate low voltage; and a first capacitor connected between the carry-in signal and the third node.

In a display device according to one or more embodiments of the present disclosure, the stage may further include: a fifth transistor configured to discharge the voltage of the second node to the gate low voltage based on a voltage of a fourth node; and a sixth transistor configured to supply a gate high voltage to the second node based on the voltage of the fourth node.

In a display device according to one or more embodiments of the present disclosure, the stage may further include: a seventh transistor configured to discharge the voltage of the fourth node to the gate low voltage based on a voltage of a fifth node; and an eighth transistor configured to supply the gate high voltage to the fourth node based on the voltage of the fifth node.

In a display device according to one or more embodiments of the present disclosure, the stage may further include: a ninth transistor configured to discharge the voltage of the fifth node to the gate low voltage based on the voltage of the fourth node; a tenth transistor configured to supply the carry-in signal to the fifth node based on the clock signal; and a second capacitor connected between the first node and the gate output signal.

The present disclosure has been described in more detail with reference to the embodiments presented herein, but the present disclosure is not limited to the embodiments presented herein. It will be apparent to those skilled in the art that various modifications can be made without departing from the technical sprit of the disclosure. Accordingly, the embodiments disclosed in the present disclosure are used not to limit but to describe the technical idea of the present disclosure, and the technical idea of the present disclosure is not limited to the embodiments presented herein. Therefore, the embodiments described above are considered in all respects to be illustrative and not restrictive. The protection scope of the present disclosure must be interpreted by the appended claims and it should be interpreted that all technical idea within a scope equivalent thereto are included in the appended claims of the present disclosure.

What is claimed is:

1. A scan driver, comprising:
a stage configured to:
receive a clock signal, an output clock signal, and a carry-in signal; and
output a gate output signal and a carry-out signal,
wherein the stage comprises:
a first transistor configured to receive the output clock signal based on a voltage of a first node and output the gate output signal;
a second transistor configured to discharge the gate output signal to a gate low voltage based on a voltage of a second node outputting the carry-out signal;
a third transistor configured to supply the voltage of the second node to the first node based on the gate low voltage; and
a fourth transistor configured to supply the voltage of the first node to the second node based on the voltage of the first node.

2. The scan driver of claim 1, wherein the stage further comprises:
a fifth transistor configured to supply a gate high voltage to the second node based on a voltage of a third node; and
a sixth transistor configured to discharge the voltage of the second node to the gate low voltage based on the voltage of the third node.

3. The scan driver of claim 2, wherein the stage further comprises:
a seventh transistor configured to supply the gate high voltage to the third node based on a voltage of a fourth node; and
an eighth transistor configured to discharge the voltage of the third node to the gate low voltage based on the voltage of the fourth node.

4. The scan driver of claim 3, wherein the stage further comprises:
a ninth transistor configured to supply the carry-in signal to the fourth node based on the clock signal; and
a first capacitor connected between the fourth node and the carry-out signal.

5. The scan driver of claim 4, wherein the stage further comprises:
a first active layer including a first material;
a first gate layer disposed on the first active layer;
a second gate layer disposed on the first gate layer;
a second active layer disposed on the second gate layer, the second active layer including a second material different from the first material; and
a third gate layer disposed on the second active layer,
wherein each of the first transistor and the third transistor includes a semiconductor region disposed in the first active layer, and
wherein each of the second transistor and the fourth transistor includes a semiconductor region disposed in the second active layer.

6. The scan driver of claim 5, wherein the first capacitor includes:
a first capacitor electrode disposed in the first gate layer and connected to a drain electrode of the ninth transistor; and
a second capacitor electrode disposed in the second gate layer and configured to receive the carry-out signal.

7. The scan driver of claim 5, wherein each of the second transistor and the fourth transistor includes a bias electrode disposed in the first gate layer and configured to receive the gate low voltage.

8. The scan driver of claim 5, wherein each of the sixth transistor and the eighth transistor includes a bias electrode disposed in the first gate layer and configured to receive the gate low voltage.

9. A display device, comprising:
a display panel comprising data lines configured to supply a data voltage, scan lines intersecting the data lines and configured to supply a scan signal, and pixels connected to the data lines and the scan lines;
a display driver configured to supply the data voltage to the data lines; and
a scan driver configured to sequentially supply scan signals to the scan lines, wherein the scan driver comprises a stage configured to:
receive a clock signal, an output clock signal, and a carry-in signal; and
output a gate output signal and a carry-out signal corresponding to the scan signal, wherein the stage comprises:
a first transistor configured to receive the output clock signal based on a voltage of a first node and output the gate output signal;
a second transistor configured to discharge the gate output signal to a gate low voltage based on a voltage of a second node outputting the carry-out signal;
a third transistor configured to supply the voltage of the second node to the first node based on the gate low voltage; and
a fourth transistor configured to supply the voltage of the first node to the second node based on the voltage of the first node.

10. The display device of claim 9, wherein the stage further comprises:
a fifth transistor configured to supply a gate high voltage to the second node based on a voltage of a third node; and
a sixth transistor configured to discharge the voltage of the second node to the gate low voltage based on the voltage of the third node.

11. The display device of claim 10, wherein the stage further comprises:
a seventh transistor configured to supply the gate high voltage to the third node based on a voltage of a fourth node; and
an eighth transistor configured to discharge the voltage of the third node to the gate low voltage based on the voltage of the fourth node.

12. The display device of claim 11, wherein the stage further comprises:
a ninth transistor configured to supply the carry-in signal to the fourth node based on the clock signal; and
a first capacitor connected between the fourth node and the carry-out signal.

13. A scan driver, comprising:
a stage configured to:
receive a clock signal, an output clock signal, and a carry-in signal; and
output a gate output signal and a carry-out signal,
wherein the stage comprises:
a first transistor configured to receive the output clock signal based on a voltage of a first node and output the gate output signal;
a second transistor configured to discharge the gate output signal to a gate low voltage based on a voltage of a second node outputting the carry-out signal;
a third transistor configured to supply the voltage of the second node to the first node based on a voltage of a third node;
a fourth transistor configured to discharge the voltage of the third node to the gate low voltage based on the gate low voltage; and
a first capacitor connected between the carry-in signal and the third node.

14. The scan driver of claim 13, wherein the stage further comprises:
a fifth transistor configured to discharge the voltage of the second node to the gate low voltage based on a voltage of a fourth node; and
a sixth transistor configured to supply a gate high voltage to the second node based on the voltage of the fourth node.

15. The scan driver of claim 14, wherein the stage further comprises:
a seventh transistor configured to discharge the voltage of the fourth node to the gate low voltage based on a voltage of a fifth node; and
an eighth transistor configured to supply the gate high voltage to the fourth node based on the voltage of the fifth node.

16. The scan driver of claim 15, wherein the stage further comprises:
a ninth transistor configured to discharge the voltage of the fifth node to the gate low voltage based on the voltage of the fourth node;
a tenth transistor configured to supply the carry-in signal to the fifth node based on the clock signal; and
a second capacitor connected between the first node and the gate output signal.

17. A display device, comprising:
a display panel comprising data lines configured to supply a data voltage, scan lines intersecting the data lines and configured to supply a scan signal, and pixels connected to the data lines and the scan lines;
a display driver configured to supply the data voltage to the data lines; and
a scan driver configured to sequentially supply scan signals to the scan lines, wherein the scan driver comprises a stage configured to:
receive a clock signal, an output clock signal, and a carry-in signal; and
output a gate output signal and a carry-out signal corresponding to the scan signal,
wherein the stage comprises:
a first transistor configured to receive the output clock signal based on a voltage of a first node and output the gate output signal;
a second transistor configured to discharge the gate output signal to a gate low voltage based on a voltage of a second node outputting the carry-out signal;
a third transistor configured to supply the voltage of the second node to the first node based on a voltage of a third node;
a fourth transistor configured to discharge the voltage of the third node to the gate low voltage based on the gate low voltage; and
a first capacitor connected between the carry-in signal and the third node.

18. The display device of claim 17, wherein the stage further comprises:
a fifth transistor configured to discharge the voltage of the second node to the gate low voltage based on a voltage of a fourth node; and
a sixth transistor configured to supply a gate high voltage to the second node based on the voltage of the fourth node.

19. The display device of claim 18, wherein the stage further comprises:
a seventh transistor configured to discharge the voltage of the fourth node to the gate low voltage based on a voltage of a fifth node; and
an eighth transistor configured to supply the gate high voltage to the fourth node based on the voltage of the fifth node.

20. The display device of claim 19, wherein the stage further comprises:
a ninth transistor configured to discharge the voltage of the fifth node to the gate low voltage based on the voltage of the fourth node;
a tenth transistor configured to supply the carry-in signal to the fifth node based on the clock signal; and
a second capacitor connected between the first node and the gate output signal.
